(19) United States
(12) Patent Application Publication
(10) Pub. No.: US 2006/0199302 A1
(43) Pub. Date: Sep. 7, 2006

(54) Semiconductor device and a manufacturing method of the same

(76) Inventors: Fujio Ito, Hanno (JP); Hiromichi Suzuki, Machida (JP); Akihiko Kameoka, Ogose (JP); Yoshitaka Takezawa, Hitachinaka (JP); Junpei Kusukawa, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/367,297

(22) Filed: Mar. 6, 2006

(30) Foreign Application Priority Data
Mar. 4, 2005 (JP) 2005-060768

(51) Int. Cl. H01L 21/00

(52) U.S. Cl. 438/106

(57) ABSTRACT

A semiconductor device is manufactured by adhering a fixing tape to plural leads of a lead frame comprising a copper alloy, mounting a semiconductor chip on a tab of the lead frame, electrically connecting the leads to electrodes a of the semiconductor chip via bonding wires, forming a sealing resin portion that seals the semiconductor chip, the tab, the bonding wires, the leads and the fixing tape, and cutting the lead frame. A binder layer of the fixing tape includes at least % by weight of an amine-curable epoxy resin as its main component, and does not include a phenol resin. The binder layer of the fixing tape further includes no more than % by weight of acrylonitrile butadiene rubber. By using this material for the binder layer of the fixing tape, migration of the copper in the leads is suppressed even when a degradation test with strict environmental degradation conditions is conducted.

### BACKGROUND OF THE INVENTION

1. Field of the Invention

The present invention relates to a semiconductor device manufacturing method and a semiconductor device, and more particularly to a technique for manufacturing a semiconductor package semiconductor device and a technique effectively applied to a semiconductor device.

2. Description of the Related Art

In recent years, various types of semiconductor packages have been used, such as, for example, a plastic package like a quad flat package (QFP). In a plastic package like a quad flat package, the semiconductor chip is mounted using a mounting binder in the center portion of a lead frame called an island. The electrodes of the semiconductor chip are electrically connected to inner lead end portions of lead portions of the lead frame via bonding wires. The semiconductor chip and the bonding wires are sealed with a sealing resin, and the outer form of the package is formed by the sealing resin. The inner lead portions of the leads are sealed inside the sealing resin, but the outer lead portions of the leads are led to the outside of the sealing resin, and these become external connection terminals of the package and are connected with solder to the terminals of the printed wiring board.

JP-A-2000-104024 discloses technology where a thermoplastic film coated with a thermosetting adhesive is used as a tape for fixing the leads of the lead frame. The thermosetting adhesive includes at least 60% by weight of an imide resin, a total of no more than 40% by weight of acetonitrile butadiene rubber and phenol resin, no more than 10% by weight of acetonitrile butadiene rubber, and 20% by weight of phenol resin.

According to the investigations of the present inventors, the following was understood.

In accompaniment with the trend to make compact and increase the number of terminals in a semiconductor device such as a quad flat package, the leads have a finer pitch, the intervals between the end portions of adjacent inner lead portions become narrow, and the widths of the end portions of the inner lead portions become thin. For example, in a quad flat package having at least about 120 leads, the pitch of the end portions of the inner lead portions becomes no more than about 0.3 mm, and the widths of the end portions of the inner lead portions become thinner than the thickness of the leads. For this reason, due to, for example, conveyance shock at the time the semiconductor device is assembled, external force resulting from the work holder, and lead frame machining residual stress at the time of heating, problems arise in the bonding with the electrodes of the semiconductor chip if even one of the inner lead portions becomes deformed, and there is the potential for problems such as short circuiting and bonding defects to occur. In order to prevent deformation of the inner lead portion ends, a fixing tape is adhered during the stage of manufacturing the lead frame.

A representative configuration of the fixing tape includes one where one side of an insulating film having a thickness of about 50 μm is coated with a thermosetting binder of about 20 μm. After the lead frame has been cut to a desired shape in a die, it is heated at a temperature of 150° C. to 200° C., and the fixing tape is pressure-adhered onto the lead frame for about 0.2 to 1 second. An example of the thermosetting binder used in the fixing tape includes one configured by acrylonitrile butadiene rubber (abbreviated simply as “NBR” below) and phenol resin. This configuration includes about 70% by weight of NBR and about 30% by weight of phenol resin.

As a thermosetting binder used for the fixing tape, JP-A-2000-104024 also proposes a thermosetting binder including at least 60% by weight of an imide resin, a total of no more than 40% by weight of acetonitrile butadiene rubber and phenol resin, no more than 10% by weight of acetonitrile butadiene rubber, and no more than 20% by weight of phenol resin.

An iron-nickel 42 alloy and a copper alloy are mainly used as the material for the lead frame, but the percentage of cases using a copper alloy has been rising in accompaniment with the increasing sophistication and integration of semiconductor devices. The reason for this is because the conductivity of the copper alloy is electrically and thermally superior to that of the iron-nickel 42 alloy. However, there is a tendency for copper to migrate due to its electric potential difference with water. The potential for a lead frame made of a copper alloy to cause insulation failure rises in accompaniment with making the pitch of the leads finer.

It was confirmed that when the binder component of the tape for fixing the leads comprises the representative configuration of NBR and phenol resin, migration of the copper in the leads occurs during aging at a temperature of at least 150° C. even if moisture is not present. It is believed that the reason for this is because the phenol resin in the binder of the fixing tape triggers ion migration of the copper.

In order to reduce this problem, JP-A-2000-104024 proposes a thermosetting binder including 60% by weight of an imide resin, a total of no more than 40% by weight of acetonitrile butadiene rubber and phenol resin, no more than 10% by weight of acetonitrile butadiene rubber, and no more than 20% by weight of phenol resin. However, the present inventors confirmed by investigation that even when this binder is used, migration of the copper in the leads occurs in a deterioration experiment under the strict environmental degradation conditions of 150° C./100 V. There is the potential for migration of the copper in the leads to cause insulation defects between the leads and reduce the reliability of the semiconductor device.

For this reason, there is a desire to suppress the migration of the copper in the leads even in a deterioration experiment with strict environmental degradation conditions and to improve the reliability of the semiconductor device.

### SUMMARY OF THE INVENTION

It is an object of the present invention to provide a technique that can improve the reliability of a semiconductor device.

This and other objects and advantages of the invention will become apparent from the description of the specification and the attached drawings.

The representative invention of the inventions disclosed in this specification is a method of manufacturing a semiconductor device, which includes adhering a member including a binder layer whose main component is an amine-curable epoxy resin to plural lead portions of a lead frame formed by a conductor material including copper.

The semiconductor device of the present invention is a semiconductor device where a member including a binder layer whose main component is an amine-curable epoxy resin is adhered to plural lead portions of a lead frame formed by a conductor material including copper.

The semiconductor device of the present invention may also be a semiconductor device where a conductor layer comprising a conductor material including copper is adhered, via a binder layer whose main component is an amine-curable epoxy resin, onto an insulating base material layer.

The effect obtained by the representative invention of the inventions disclosed in this specification is that the reliability of a semiconductor device can be improved.

### BRIEF DESCRIPTION OF THE DRAWINGS

Embodiments of the invention will be described below with reference to the attached drawings, wherein:

FIG. 1 is a plan view of a semiconductor device pertaining to a first embodiment of the invention;

FIG. 2 is a plan perspective view of the semiconductor device pertaining to the first embodiment of the invention;

FIG. 3 is a cross-sectional view of the semiconductor device pertaining to the first embodiment of the invention;

FIG. 4 is a plan view of relevant portions of the semiconductor device pertaining to the first embodiment of the invention;

FIG. 5 is a cross-sectional view of relevant portions of the semiconductor device pertaining to the first embodiment of the invention;

FIG. 6 is a plan view during the manufacturing process of the semiconductor device pertaining to the first embodiment of the invention;

FIG. 7 is a cross-sectional view during the manufacturing process of the same semiconductor device of FIG. 6;

FIG. 8 is a plan view during the manufacturing process of the semiconductor device continued from FIG. 6;

FIG. 9 is a cross-sectional view during the manufacturing process of the same semiconductor device of FIG. 8;

FIG. 10 is a plan view during the manufacturing process of the semiconductor device continued from FIG. 8;

FIG. 11 is a cross-sectional view during the manufacturing process of the same semiconductor device of FIG. 10;

FIG. 12 is a plan view during the manufacturing process of the semiconductor device continued from FIG. 10;

FIG. 13 is a cross-sectional view during the manufacturing process of the same semiconductor device of FIG. 12;

FIG. 14 is a plan view during the manufacturing process of the semiconductor device continued from FIG. 12;

FIG. 15 is a cross-sectional view during the manufacturing process of the same semiconductor device of FIG. 14;

FIG. 16 is a plan view during the manufacturing process of the semiconductor device continued from FIG. 14;

FIG. 17 is a cross-sectional view during the manufacturing process of the same semiconductor device of FIG. 16;

FIG. 18 is cross-sectional view of relevant portions of a semiconductor device when the semiconductor device is manufactured using a fixing tape of a comparative example;

FIG. 19 is an explanatory diagram schematically showing a binder layer of a fixing tape pertaining to the first embodiment of the invention;

FIG. 20 is an explanatory diagram schematically showing the binder layer of the fixing tape pertaining to the first embodiment of the invention;

FIG. 21 is an explanatory chart showing the solubility parameters of various kinds of substances;

FIG. 22 is an explanatory diagram schematically showing a binder layer of a fixing tape of a comparative example;

FIG. 23 is an explanatory diagram schematically showing a binder layer of a fixing tape of a comparative example;

FIG. 24 is an explanatory diagram showing the structure of bisphenol A epoxy resin;

FIG. 25 is an explanatory diagram showing the structure of an example of a phenol resin;

FIG. 26 is an explanatory diagram showing the structure of another example of a phenol resin;

FIG. 27 is a cross-sectional view of a semiconductor device pertaining to a second embodiment of the invention;

FIG. 28 is a plan view during the manufacturing process of the semiconductor device of FIG. 27;

FIG. 29 is a plan perspective view of a semiconductor device pertaining to a third embodiment of the invention;

FIG. 30 is a cross-sectional view of the semiconductor device pertaining to the third embodiment of the invention;

FIG. 31 is a plan view of relevant portions of the semiconductor device pertaining to the third embodiment of the invention;

FIG. 32 is a cross-sectional view of relevant portions of the semiconductor device pertaining to the third embodiment of the invention;

FIG. 33 is a plan view during the manufacturing process of the semiconductor device pertaining to the third embodiment;

FIG. 34 is a cross-sectional view during the manufacturing process of the same semiconductor device of FIG. 33;

FIG. 35 is a plan view during the manufacturing process of the semiconductor device continued from FIG. 33;

FIG. 36 is a cross-sectional view during the manufacturing process of the same semiconductor device of FIG. 35;

FIG. 37 is a plan view during the manufacturing process of the semiconductor device continued from FIG. 35;

FIG. 38 is a cross-sectional view during the manufacturing process of the same semiconductor device of FIG. 37;

FIG. 39 is a plan view during the manufacturing process of the semiconductor device continued from FIG. 37;

FIG. 40 is cross-sectional view during the manufacturing process of the same semiconductor device of FIG. 39;

FIG. 41 is a plan perspective view of a semiconductor device pertaining to a fourth embodiment of the invention;

FIG. 42 is a cross-sectional view of the semiconductor device pertaining to the fourth embodiment of the invention;

FIG. 43 is a plan view of relevant portions of the semiconductor device pertaining to the fourth embodiment of the invention;

FIG. 44 is a cross-sectional view of relevant portions of the semiconductor device pertaining to the fourth embodiment of the invention;

FIG. 45 is a cross-sectional view during the manufacturing process of the semiconductor device pertaining to the fourth embodiment of the invention;

FIG. 46 is a cross-sectional view during the manufacturing process of the semiconductor device continued from FIG. 45;

FIG. 47 is a cross-sectional view during the manufacturing process of the semiconductor device continued from FIG. 46;

FIG. 48 is a cross-sectional view during the manufacturing process of the semiconductor device continued from FIG. 47;

FIG. 49 is a cross-sectional view during the manufacturing process of the semiconductor device continued from FIG. 48;

FIG. 50 is a plan perspective view of a semiconductor device pertaining to a fifth embodiment of the invention;

FIG. 51 is a cross-sectional view of the semiconductor device pertaining to the fifth embodiment of the invention;

FIG. 52 is a cross-sectional view of relevant portions of the semiconductor device pertaining to the fifth embodiment of the invention;

FIG. 53 is a cross-sectional view during the manufacturing process of the semiconductor device pertaining to the fifth embodiment of the invention;

FIG. 54 is a cross-sectional view during the manufacturing process of the semiconductor device continued from FIG. 53;

FIG. 55 is a plan view during the manufacturing process of the same semiconductor device of FIG. 54;

FIG. 56 is a cross-sectional view during the manufacturing process of the semiconductor device continued from FIG. 54;

FIG. 57 is a cross-sectional view during the manufacturing process of the semiconductor device continued from FIG. 56;

FIG. 58 is a cross-sectional view during the manufacturing process of the semiconductor device continued from FIG. 57;

FIG. 59 is a cross-sectional view during the manufacturing process of the semiconductor device continued from FIG. 58;

FIG. 60 is a plan perspective view of a semiconductor device pertaining to a sixth embodiment of the invention;

FIG. 61 is a cross-sectional view of the semiconductor device pertaining to the sixth embodiment of the invention;

FIG. 62 is a cross-sectional view of relevant portions of the semiconductor device pertaining to the sixth embodiment of the invention;

FIG. 63 is a cross-sectional view during the manufacturing process of the semiconductor device pertaining to the sixth embodiment of the invention;

FIG. 64 is a cross-sectional view during the manufacturing process of the semiconductor device continued from FIG. 63;

FIG. 65 is a plan view during the manufacturing process of the same semiconductor device of FIG. 64;

FIG. 66 is a cross-sectional view during the manufacturing process of the semiconductor device continued from FIG. 64; and

FIG. 67 is a cross-sectional view during the manufacturing process of the semiconductor device continued from FIG. 66.

### DETAILED DESCRIPTION OF THE INVENTION

Although embodiments of the invention are illustrated by division into a plurality of sections or embodiments if expediently necessary, these are not mutually irrelevant to one another unless otherwise stated. More particularly, one may be in relation with a modification, details, supplemental explanation and the like of part or all of others. In the following embodiments, where reference is made to the parameters of elements (including the number, numerical value, quantity, range and the like), they should not be construed as limiting to specified values or numbers, respectively, except the case where they are specified or limited to a specific value apparently in principle. Moreover, it is as a matter of course that constituent elements (including steps) in the following embodiments are not always essential except the case where otherwise specified or where such elements are considered to be apparently essential in principle. Likewise, if reference is made to the shape, positional relation and the like of the constituent elements, then substantially like or similar shapes and the like are also within the scope of the invention except the case where otherwise specified or where such shapes should not be apparently included in principle. This is true of the above-indicated numbers and ranges.

Embodiments of the present invention will be described in detail below. In all of the drawings for describing the invention, the same reference numerals will be given to members having the same functions, and repetitive description of those members will be omitted. In the following embodiments, description of the same or similar portions will in principle be omitted unless necessary.

Also, in the drawings used in the embodiments, sometimes hatching is omitted in order to facilitate viewing of the drawings, even if the drawing is a cross-sectional view. And sometimes, hatching is added in order to facilitate viewing of the drawings, even if the drawing is a plan view.

### First Embodiment

A semiconductor device pertaining to a first embodiment of the invention will be now described with reference to the drawings.

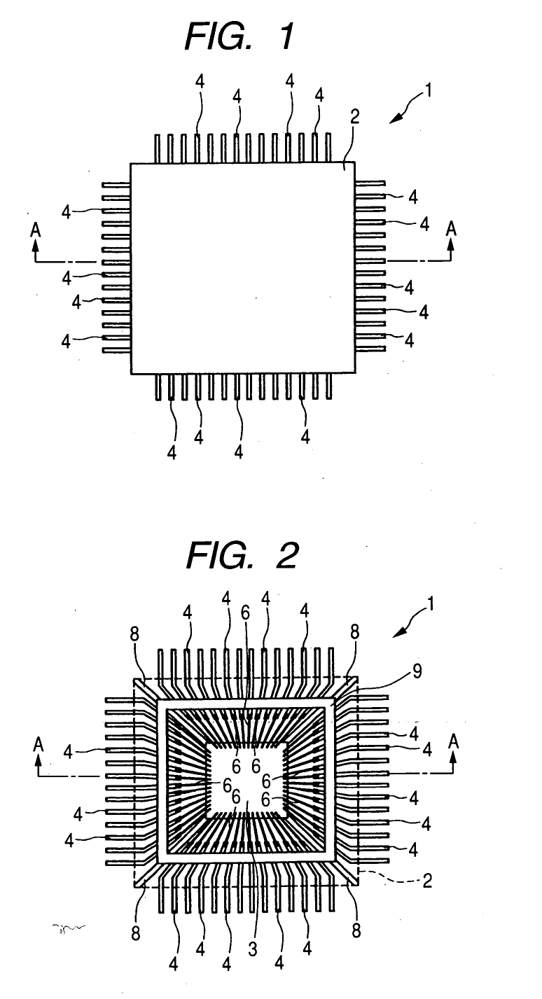

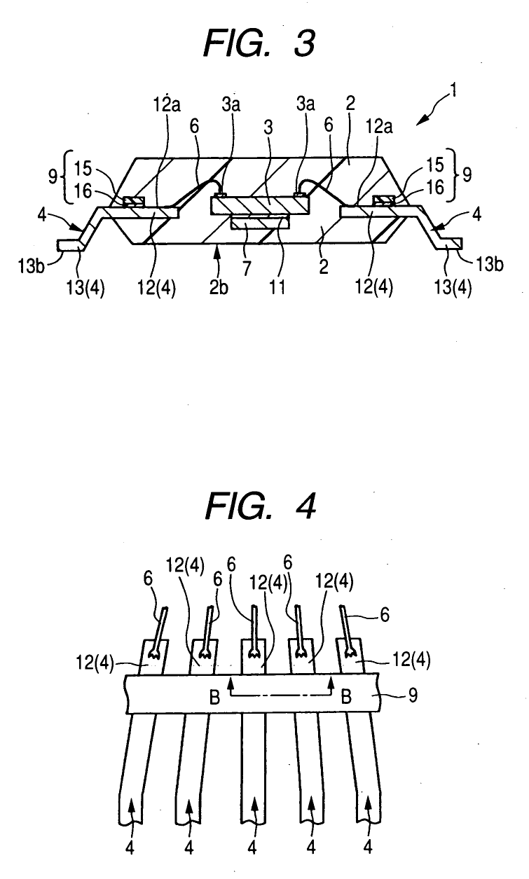

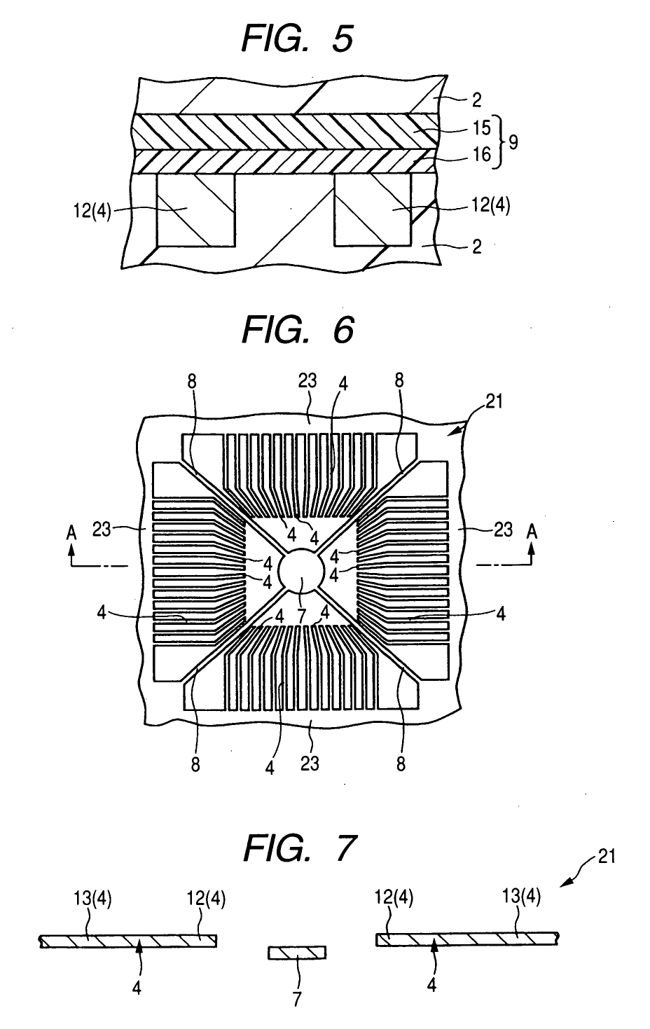

FIG. 1 is a plan (top) view of a semiconductor device 1 pertaining to the first embodiment of the invention. FIG. 2 is a plan (top) perspective view, FIG. 3 is a cross-sectional view (side sectional view), FIG. 4 is a plan view of relevant portions (plan perspective view), and FIG. 5 is a cross-sectional view of relevant portions (partially enlarged cross-sectional view). FIG. 2 corresponds to a plan (top) view when the semiconductor device 1 is seen through a sealing resin portion 2, and FIG. 5 corresponds to a cross-sectional view of relevant portions (partially enlarged cross-sectional view) when the semiconductor device 1 is seen through the sealing resin portion 2. The cross section along line A-A of FIGS. 1 and 2 substantially corresponds to FIG. 3. The cross section along line B-B of FIG. 4 substantially corresponds to FIG. 5.

The semiconductor device 1 of the present embodiment is a resin-sealed semiconductor package manufactured using a lead frame, and is, for example, a quad flat package (QFP) semiconductor device.

The semiconductor device 1 of the present embodiment shown in FIGS. 1 to 5 includes: a sealing resin portion (sealing portion) 2; a semiconductor chip (semiconductor element) 3 sealed by the sealing resin portion 2; plural leads (lead portions) 4 formed by conductors; plural bonding wires (wires, fine metal wires) 6 that are sealed by the resin sealing portion 2 and electrically connect the plural leads 4 to plural electrodes (bonding pads) 3a on the surface of the semiconductor chip 3; a tab (island, die pad portion, chip mounting portion) 7 that is a chip mounting portion on which the semiconductor chip 3 is mounted; plural dangling leads (conductor portions) 8 connected to the tab 7; and a fixing tape 9 adhered to the plural leads 4.

The sealing resin portion 2 comprises a thermosetting resin material and can include a filler and the like. For example, the sealing resin portion 2 can be formed using an epoxy resin that includes a filler. The semiconductor chip 3, the leads 4, the bonding wires 6, the tab 7, the dangling leads 8 and the fixing tape 9 are sealed and protected by the sealing resin portion 2.

The semiconductor chip 3 is made by forming various semiconductor elements or semiconductor integrated circuits on a semiconductor substrate (semiconductor wafer) comprising single crystal silicon, for example, grinding the undersurface of the semiconductor substrate as needed, and then dicing the semiconductor substrate into the semiconductor chips 3. The semiconductor chip 3 is mounted on the tab 7 such that its surface (the side on which the semiconductor element is formed) faces upward, and the undersurface (the opposite side of the side on which the semiconductor element is formed) of the semiconductor chip 3 is adhered (bonded), via a bonding material (die bonding material) such as silver paste, to the tab 7 comprising a conductor.

The plural electrodes (bonding pads, pad electrodes) 3a are formed on the surface of the semiconductor chip 3. The electrodes 3a are electrically connected to the semiconductor element or semiconductor integrated circuit formed on the semiconductor chip 3. The electrodes 3a on the surface of the semiconductor chip 3 are electrically connected, via the bonding wires 6 comprising fine metal wires such as gold (Au) wires, to upper surfaces 12a of inner lead portions 12 of the leads 4.

The leads 4 comprise a conductor material (metal material) including copper or copper such as a copper alloy. The leads 4 are disposed around the tab 7 such that their ends face the tab 7. The leads 4 include inner lead portions 12 embedded in the sealing resin portion 2 and outer lead portions 13 exposed to the outside of the sealing resin portion 2. The inner lead portions 12 and the outer lead portions 13 are integrally formed to configure the leads 4.

The inner lead portions 12 of the leads 4 are sealed inside the sealing resin portion 2, and the bonding wires 6 are connected (bonded) to the upper surfaces 12a of the inner lead portions 12 that can function as bonding portions of the leads 4.

The outer lead portions 13 of the leads 4 protrude and are exposed from the side surface of the sealing resin portion 2, and can function as external connection terminal portions of the semiconductor device 1. The outer lead portions 13 of the leads 4 are bent as needed. For example, lower surfaces 13b in regions in the vicinities of the end portions (end portions opposite from the sides connected to the inner lead portions 12) of the outer lead portions 13 are configured such that they are positioned on substantially the same plane as an undersurface (lower surface, bottom surface) 2b of the sealing resin portion 2. Thus, when the undersurface (undersurface 2b of the sealing resin portion 2) side of the semiconductor device 1 is mounted on a mounting substrate (not shown), the connection of the terminals on the mounting substrate and the lower surfaces 13b of the outer lead portions 13 of the semiconductor device 1 can be facilitated. That is, the undersurface (bottom surface) side of the semiconductor device 1 corresponding to the undersurface 2b of the sealing resin portion 2 becomes the mounting surface of the semiconductor device 1, and the (lower surfaces 13b of the) outer lead portions 13 configure the external terminals (external connection terminals) of the semiconductor device 1. Also, the end portions (end portions opposite from the sides connected to the inner lead portions 12) of the outer lead portions 13 are formed by cut surfaces generated by a cutting step when manufacturing the semiconductor device 1. The space between the inner lead portions 12 of the leads 4 and the semiconductor chip 3, and the space between adjacent inner lead portions 12, are filled with the material configuring the sealing resin portion 2 to ensure that they do not come into contact with each other.

The plural (here, four) dangling leads 8 are connected to the tab 7. One end of each of the dangling leads 8 is connected to the tab 7, and the dangling leads 8 extend outward of the tab 7. The dangling leads 8 are disposed in order to retain or support the tab 7 on (the framework of) a lead frame used in the manufacture of the semiconductor device 1, and are cut from the lead frame after the formation of the sealing resin portion 2, such that cut surfaces (not shown), which are side surfaces (i.e., end portions opposite from the end portions connected to the tab 7) generated by cutting the dangling leads 8, are exposed at the side surface of the sealing resin portion 2. The leads 4, the tab 7 and the dangling leads 8 all comprise a conductor material, such as a common conductor material used in the lead frame (corresponding to a later-described lead frame 21) for the manufacture of the semiconductor device 1, i.e., a conductor material (metal material) including copper or copper such as a copper alloy.

The fixing tape 9 is adhered (bonded) to the upper surfaces 12a of the inner lead portions 12 of the plural leads 4 such that it straddles them. The fixing tape 9 includes the function of fixing the (inner lead portions 12 of the) plural leads 4 at the time of wire bonding and fixing the plural leads 4 such that they do not move due to the injection pressure of the resin when the sealing resin portion 2 is formed. The fixing tape 9 comprises a tape base material layer (base material layer) 15 and a binder (adhesive) layer 16 on the tape base material layer 15. The tape base material layer 15 comprises an insulating film such as a polyimide film. It is more preferable for the tape base material layer 15 to be formed by a thermoplastic insulating film.

The binder layer 16 is a material layer (binder layer) for imparting adhesiveness to the fixing tape 9. In the present embodiment, the binder layer 16 includes an amine-curable epoxy resin, and not a phenol resin, as the main component of the binder, and more preferably also includes acrylonitrile butadiene rubber (NBR).

The binder layer 16 having a thickness of about 20 μm, for example, is formed one side of the tape base material layer 15 having a thickness of about 50 μm, for example. As described later, the fixing tape 9 is adhered to the upper surfaces 12a of the inner lead portions 12 of the plural leads 4 via the binder layer 16, whereby the inner lead portions 12 are adhered and fixed to the tape base layer 15 by the binder layer 16, so that the inner lead portions 12 of the plural leads 4 can be fixed during the manufacturing process of the semiconductor device 1. That is, the inner lead portions 12 of the plural leads 4 can be fixed by the fixing tape 9 during the manufacturing process of the semiconductor device 1.

Next, the manufacturing process of the semiconductor device of the present embodiment will be described.

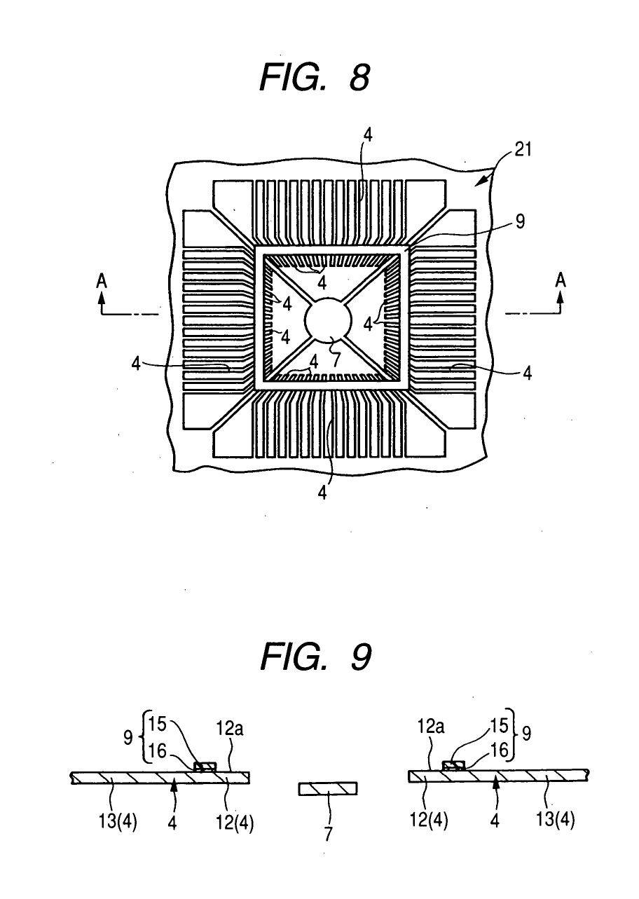

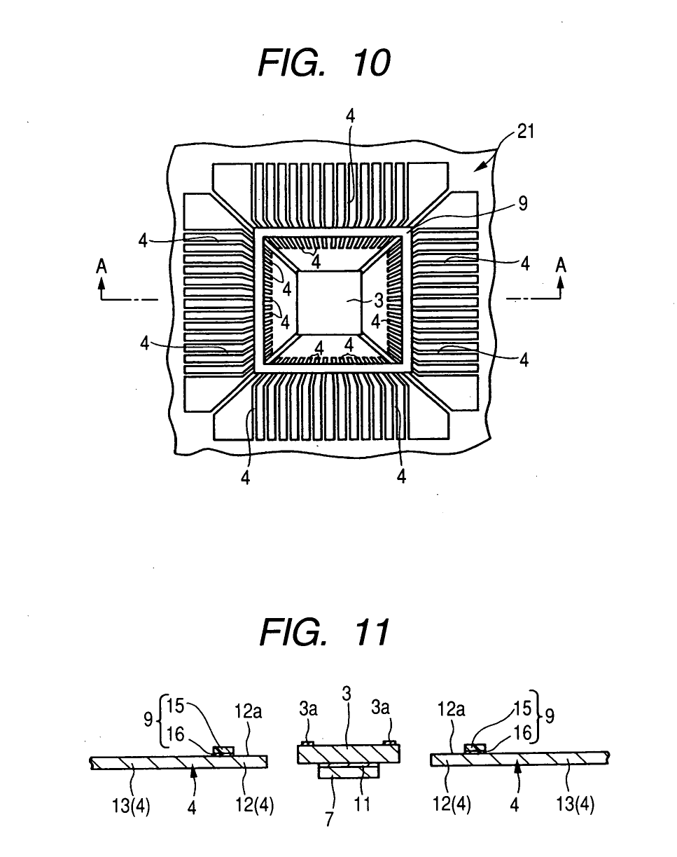

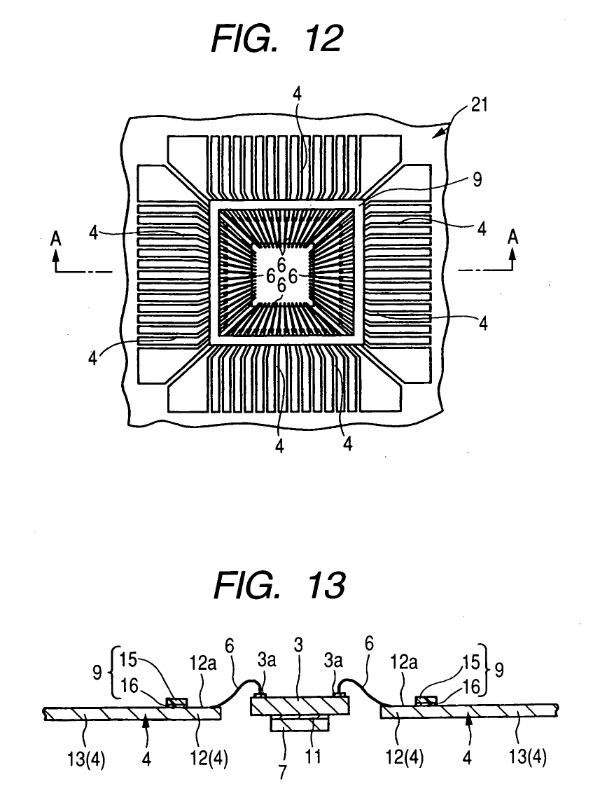

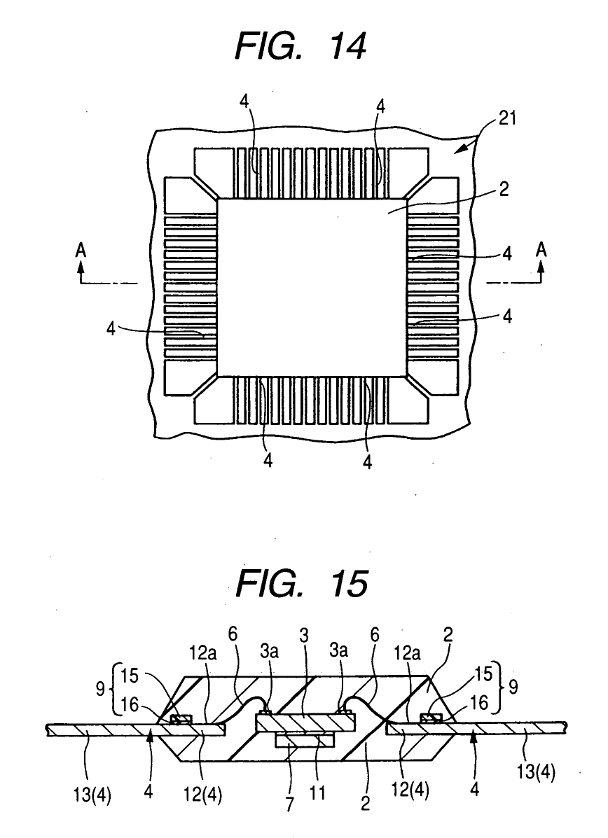

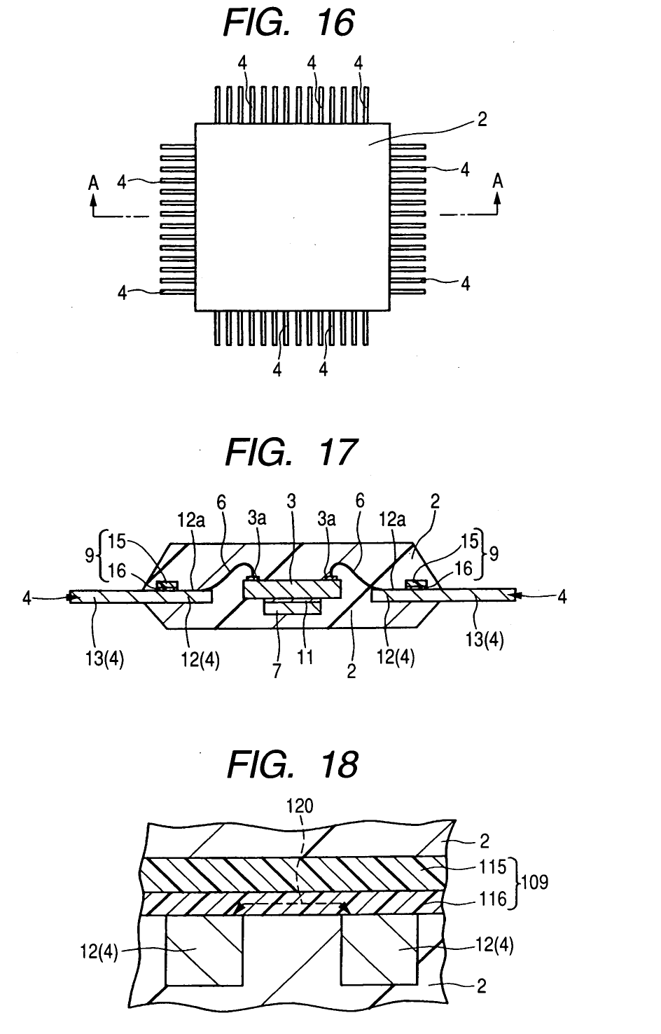

FIGS. 6 to 17 are plan views or cross-sectional views (cross-sectional views of relevant portions) showing the manufacturing process of the semiconductor device 1 of the present embodiment. Of FIGS. 6 to 17, FIGS. 6, 8, 10, 12, 14 and 16 are plan views (plan views of relevant portions), and FIGS. 7, 9, 11, 13, 15 and 17 are cross-sectional views (cross-sectional views of relevant portions). FIGS. 6 and 7 correspond to the same process stage, FIGS. 8 and 9 correspond to the same process stage, FIGS. 10 and 11 correspond to the same process stage, FIGS. 12 and 13 correspond to the same process stage, FIGS. 14 and 15 correspond to the same process stage, and FIGS. 16 and 17 correspond to the same process stage. The cross-sectional views of FIGS. 7, 9, 11, 13, 15 and 17 show a cross section along line A-A of FIGS. 1 and 2, i.e., the same cross section as in FIG. 3. Line A-A is shown at positions in FIGS. 6, 8, 10, 12, 14 and 16 corresponding to the position of line A-A in FIGS. 1 and 2. A region corresponding to one semiconductor package of the lead frame 21 is shown in the plan views of FIGS. 6, 8, 10, 12, 14 and 16 (a region from which one semiconductor device 1 is manufactured).

In manufacturing the semiconductor device 1, as shown in FIGS. 6 and 7, first, the lead frame 21 is prepared. The lead frame 21 comprises a conductor material including copper or copper like a copper alloy, for example. The lead frame 21 includes: the tab 7 for mounting the semiconductor chip 3; the dangling leads 8 that retain or support the tab 7 on the framework 23, with one end of each of the dangling leads 8 being connected to a framework 23 and the other ends being connected to the four corners of the tab 7; and the leads 4, with one end of each being disposed such that it is separated from and faces the tab 7 and the other end of each being connected to the framework 23. For the lead frame 21, an etching frame comprising a metal plate (copper plate or copper alloy plate) that has been etched, or a stamping frame (press frame) comprising a metal plate (copper plate or copper alloy plate) that has been stamped (pressed), can be used.

Next, as shown in FIGS. 8 and 9, the fixing tape 9 is adhered onto the plural leads 4 of the lead frame 21. The fixing tape 9 is a member (tape or film member) for fixing the plural leads 4, and comprises the tape base material layer 15 and the binder layer 16 on the tape base material layer 15. The tape base material layer 15 comprises an insulating film, such as a polyimide film. A thermosetting binder including an amine-curable epoxy resin is used as the binder layer 16. For example, a tape where the binder layer 16 having a thickness of about 20 μm is formed (coated, applied) on one side of the tape base material layer 15 having a thickness of about 20 μm can be used as the fixing tape 9. The material configuring the binder layer 16 will be described in greater detail later.

When the fixing tape 9 is to be adhered onto the plural leads 4 of the lead frame 21, the fixing tape 9 is adhered on the upper surfaces 12a of the inner lead portions 12 of the plural leads 4 such that the binder layer 16 contacts (faces) the upper surfaces 12a of the inner lead portions 12 of the leads 4. That is, the fixing tape 9 including the binder layer 16 is adhered, via the binder layer 16, on the upper surfaces 12a of the inner lead portion 12 of the plural leads 4 of the lead frame 21. For example, the upper surfaces 12a of the inner lead portions 12 can be adhered and fixed to the binder layer 16 of the fixing tape 9 by etching or die-pressing a metal plate (copper plate or copper alloy plate) into a predetermined shape to manufacture the lead frame 21, heating the lead frame 21 to a predetermined temperature (e.g., about 150 to about 200° C.), and then pressing (pressure-adhering) the fixing tape 9 onto the upper surfaces 12a of the inner lead portions 12 of the plural leads 4 for a predetermined amount of time (e.g., about 0.2 to about 1 second). By adhering the fixing tape 9 onto the upper surfaces 12a of the inner lead portions 12, the inner lead portions 12 of the plural leads 4 are fixed, and the inner lead portions 12 can be prevented from being deformed in a later step.

After the lead frame 21 (the lead frame 21 as shown in FIGS. 8 and 9), where the plural leads 4 are fixed by the fixing tape 9, has been prepared in this manner, the semiconductor device is manufactured (assembled) as follows, for example.

First, as shown in FIGS. 10 and 11, a die bonding step is conducted to mount the semiconductor chip 3 on the tab 7 of the lead frame 21. In this die bonding step, the semiconductor chip 3 is adhered (bonded) via a jointing material 11 onto the tab 7 of the lead frame 21. For example, silver (Ag) paste can be used for the jointing material 11. The semiconductor chip 3 can be adhered to, and mounted on, the tab 7 by disposing the semiconductor chip 3 on the tab 7 via silver paste (jointing material 11) including a thermosetting resin such as a thermosetting epoxy resin, and heating the silver paste (jointing material 11) to cure it. The silver paste (jointing material 11) is heated for about two minutes at about 250° C., for example. In this manner, the semiconductor chip 3 is mounted on the tab 7. For this reason, in the step of die bonding the semiconductor chip 3 (step of mounting the semiconductor chip 3 on the tab 7), the lead frame 21 and the fixing tape 9 are also heated.

Next, as shown in FIGS. 12 and 13, a wire bonding step is conducted to electrically connect, via the plural bonding wires 6, the plural electrodes 3a of the semiconductor chip 3 to the upper surfaces 12a of the inner lead portions 12 of the plural leads 4 of the lead frame 21.

When wire-bonding the bonding wires 6, in order to raise the connection strength of the bonding wires 6, it is preferable to heat the region in the vicinity of the leads 4 and the electrodes 3a of the semiconductor chip 3, which is a wire bonding region, to a predetermined temperature suited for wire bonding in a state where the lead frame 21 has been mounted on a heat stage, and then electrically connect the electrodes 3a of the semiconductor chip 3 to the inner lead portions 12 of the leads 4 via the bonding wires 6. For example, wire bonding is conducted while heating the tab 7 and the leads 4. For this reason, in the wire bonding step, the lead frame 21 and the fixing tape 9 are also heated. For example, they are heating for about thirty seconds to about three minutes at about 200° C. to about 250° C.

Next, as shown in FIGS. 14 and 15, a mold step (e.g., a transfer mold step) is conducted to seal the semiconductor chip 3 and the bonding wires 6 with the sealing resin portion 2. In the mold step, the inner lead portions 12 of the leads 4 of the lead frame 21, the tab 7, the dangling leads 8 and the fixing tape 9 are also sealed by the sealing resin portion 2.

Next, as shown in FIGS. 16 and 17, the lead frame 21 is cut at predetermined positions and separated into pieces. After the lead frame 21 has been cut, the outer lead portions 13 of the leads 4 protruding from the sealing resin portion 2 are molded. In this manner, semiconductor devices (semiconductor packages) divided into pieces, i.e., the semiconductor devices 1 shown in FIGS. 1 to 5, are formed. After the sealing resin portion 2 has been formed, plating can be conducted before or after the lead frame 21 is cut, so that a plating layer (e.g., a solder plating layer) is formed on the outer lead portions 13 of the semiconductor device 1.

Thereafter, a marking step and a sorting step are conducted with respect to the semiconductor devices 1, and semiconductor devices 1 sorted as good products in the sorting step are shipped as products (semiconductor packages).

As semiconductor devices (semiconductor packages) become more compact and the number of their terminals increases, the pitch of the leads becomes finer, the intervals between the end portions of the adjacent inner lead portions 12 become narrow, and the widths of the end portions of the inner lead portions 12 become thin. For example, in a quad flat package including at least about 120 leads, the pitch of the end portions of the inner lead portions becomes no more than about 0.3 mm, and the widths of the end portions of the inner lead portions become thinner than the thickness of the leads. When the shape of the end portions of the inner lead portions 12 becomes thin, it becomes easy for the inner lead portions 12 to become deformed. When the inner lead portions 12 become deformed, there is the potential for defects in the wire bonding to the inner lead portions 12 to occur. Also, when the end portions of the inner lead portions 12 come into close proximity to each other, the inner lead portions 12 contact each other and short circuit if the inner lead portions 12 become even slightly deformed during the manufacturing process of the semiconductor device 1. There is the potential for deformation to occur in the inner lead portions due to, for example, conveyance shock at the time the semiconductor device is assembled, external force resulting from the work holder, and lead frame machining residual stress at the time of heating. And if even one of the inner lead portions becomes deformed, problems arise in the electrical connection between the electrodes of the semiconductor chip and the inner lead portions, and there is the potential for problems such as short circuiting and connection (bonding) defects to occur. If the inner lead portions 12 of the lead frame 21 become deformed during the manufacturing process of the semiconductor device 1, connection problems and short circuiting problems occur, the manufactured semiconductor device becomes a defective product and must be disposed of during the inspection step, and the manufacturing yield of the semiconductor device drops.

In the present embodiment, the inner lead portions 12 can be prevented from being deformed in the later step of assembling the semiconductor device by adhering and fixing the fixing tape 9 to the leads 4 of the lead frame 21 at the stage when the lead frame 21 is manufactured. Thus, the reliability of the connection of the bonding wires 6 to the inner lead portions 12 can be improved, and short circuiting between adjacent inner lead portions 12 can be prevented. By fixing the inner lead portions 12 of the plural leads 4 of the lead frame 21 using the fixing tape 9 in this manner, deformation of the inner lead portions 12 can be prevented, the occurrence of problems such as connection problems and short circuiting problems resulting from deformation of the inner lead portions 12 can be prevented, and the manufacturing yield of the semiconductor device can be improved.

Next, the fixing tape 9 used in the present embodiment, and more particularly the binder layer 16 of the fixing tape 9, will be described in greater detail.

The tape base material layer 15 of the fixing tape 9 comprises an insulator material such as an insulating film, such as polyimide film. A thermosetting binder is used for the binder layer 16 of the fixing tape 9, but in the present embodiment a thermosetting binder including an amine-curable epoxy resin as its main component is used as the binder layer 16.

FIG. 18 is a cross-sectional diagram of relevant portions of a manufactured semiconductor device when the semiconductor device is manufactured using a fixing tape 109 of a comparative example instead of the fixing tape 9 of the present embodiment.

The fixing tape 109 of the comparative example includes a tape base material layer 115 and a binder layer 116 formed on the tape base material layer 115. The tape base material layer 115 comprises a polyimide film. In contrast to the binder layer 16 of the fixing tape 9 of the present embodiment, the binder layer 116 of the fixing tape 109 of the comparative example is a binder layer including a phenol resin as its binder component. The binder layer 116 also includes NBR.

The problem when a semiconductor device is assembled (manufactured) using the fixing tape 109 by forming the binder layer 116 with a binder including a phenol resin as its binder component, as in the fixing tape 109 of the comparative example, will be described.

Because the binder layer 116 of the fixing tape 109 uses a phenol resin and NBR as the binder component, the binder component of the binder layer 116 thermally dissolves at the time of heating and generates a large out-gas component, and there is the potential for this to adhere to and pollute the surfaces and the like of the leads 4. Examples of the out-gas generated from the NBR include methanol, acetone, and methyl ethyl ketone, and examples of the out-gas generated from the phenol resin include phenol and methanol. If the surfaces of the leads 4 are polluted by the out-gas from the binder layer 116, this triggers connection defects (non-adherence at the time of thermocompression bonding) when the bonding wires 6 are connected to the inner lead portions 12, and results in the lowering of the adhesion between the sealing resin portion 2 and the leads 4 after the sealing resin portion 2 is formed. This lowers the manufacturing yield of the semiconductor device.

If there is a lot of out-gas from the binder layer 116, it becomes easy for the copper oxide film of the lead frame 21 separate when the lead frame 21 is formed with copper or a copper alloy. That is, at the surface of the lead frame 21 to which out-gas adheres, the formation of the oxide film by heating during the assembly step of the semiconductor device becomes unstable, it becomes easy for the oxide film to separate even if the oxide film is thin, and this triggers separation at the boundary with the sealing resin portion 2 after the sealing resin portion 2 is formed.

During the assembly step of the semiconductor device, silver (Ag) paste or the like is used as the jointing material 11 when the semiconductor chip 3 is mounted on the tab 7, but this is heated (e.g., heated for about two minutes at about 250° C.) when curing the jointing material 11, which takes a thermal history, and this is heated (e.g., heated for about thirty seconds to about three minutes at about 200° C. to about 250° C.) when the bonding wires 6 are wire bonded, which takes a thermal history. During these steps accompanied by heating (the step of curing the jointing material 11 and the wire bonding step), there is the potential for a lot of out-gas to be generated from the thermosetting binder (binder layer 116) of the fixing tape 109 that is only provisionally adhered to the lead frame 21 at the stage of manufacturing the lead frame 21.

An iron-nickel 42 alloy and a copper alloy are mainly used as the material for the lead frame, but the percentage of cases using a copper alloy has been rising in accompaniment with the increasing sophistication and integration of semiconductor devices. The reason for this is because the conductivity of the copper alloy is electrically and thermally superior to that of the iron-nickel 42 alloy. However, there is a tendency for copper to easily migrate due to its electric potential difference with water. The potential for a lead frame made of a copper alloy to cause insulation failure rises in accompaniment with making the pitch of the leads finer.

It was confirmed that when the binder component (binder layer 116) of the fixing tape 109 for fixing the leads of the comparative example comprises NBR and phenol resin, migration of the copper occurs during aging at a high temperature of at least 150° C. even if moisture is not present. The present inventors discovered that the reason for this is that the phenol resin in the binder layer 116 of the fixing tape 109 triggers ion migration of the copper.

In order to reduce this problem, JP-A-2000-104024 proposes, as a thermosetting binder (binder layer 116) used in the fixing tape 109, a thermosetting binder including 60% by weight of an imide resin, a total of no more than 40% by weight of acetonitrile butadiene rubber and phenol resin, no more than 10% by weight of acetonitrile butadiene rubber, and no more than 20% by weight of phenol resin. However, it was confirmed by the investigations of the present inventors that even when this binder layer is used, copper migration occurred in a deterioration experiment under the strict environmental degradation conditions of 150° C./100 V.

Insulation failure resulting from migration of the copper will be described with reference to FIG. 18. In FIG. 18, migration of the copper of the inner lead portions 12 comprising a copper alloy occurs between adjacent inner lead portions 12, and the copper in the inner lead portions 12 disperses through the binder layer 116 of the fixing tape 109. Thus, migration of the copper occurs on a path 120 (copper dispersion path, region in which copper migration occurs) schematically represented by the arrow in FIG. 18, and the copper in the inner lead portions 12 disperses through the binder layer 116. If adjacent inner lead portions 12 become electrically conductive (short circuit) or come into proximity with each other via the path 120 in which copper migration occurs, insulation failure between the adjacent inner lead portions 12 (problem of short circuiting when a voltage is applied between the adjacent inner lead portions 12) occurs.

The present inventors investigated in detail defects originating in the binder layer (binder layer 116) of the fixing tape for fixing the leads. As a result, the following were discovered.

As a result of investigating in detail the mechanism of the occurrence of migration under the strict environmental degradation conditions of 150° C./100 V, the present inventors discovered that the presence not only of ionic impurities where copper ions form a colloid such as copper hydroxide but also of a low-molecular-weight compound included in extremely miniscule amounts in the binder resin (volatile component such as a solvent) remarkably lowers anti-migration characteristics. The following three causes are mainly conceivable as the causes of migration occurrence due to the low-molecular-weight compound (volatile component such as a solvent).

The first cause is the plasticization of the base resin due to the low-molecular-weight compound (volatile component such as a solvent). This lowers the elasticity modulus of the binder layer (binder layer 116) and increases the ion mobility (mobility of copper ions) in the binder layer (binder layer 116).

The second cause is the expansion of the base resin caused by the low-molecular-weight compound (volatile component such as a solvent). This increases the free volume between the molecules in the resin of the binder layer (binder layer 116) and increases the ion mobility (mobility of copper ions) in the binder layer (binder layer 116).

The third cause is the carrier action of the copper (Cu) ions caused by the low-molecular-weight compound (volatile component such as a solvent). Due to the low-molecular-weight compound (volatile component such as a solvent), the copper ions take a solvate-like structure (state where a low-molecular-weight compound such as methanol is bonded to the copper ions), and this increases the ion mobility (mobility of copper ions) in the binder layer (binder layer 116).

If a low-molecular-weight compound (volatile component such as a solvent) is present in the binder layer (binder layer 116), the ion mobility of the copper in the binder layer (binder layer 116) increases due to the aforementioned three causes (first, second, and third causes), it becomes easy for migration of the copper to occur, and this lowers the anti-migration characteristics.

In relation to the aforementioned three causes, if a low-molecular-weight compound (volatile component such as a solvent) is present in the binder layer, it acts such that the low-molecular-weight compound bonds to the copper ions, the copper ions take a solvate-like structure, and the mobility increases over the state of the copper ions alone. If that which bonds to the copper ions at this time is a high-molecular-weight compound, the size of the solvate-like structure increases, whereby it becomes more difficult for it to move through the binder layer. But if that which bonds to the copper ions is a low-molecular-weight compound such as methanol, the size of the solvate-like structure also becomes smaller and it becomes more difficult for it to move through the binder layer, which acts to increase the ion mobility (mobility of copper ions) in the binder layer.

As something which lowers the migration resistance as the low-molecular-weight compound (volatile component such as a solvent), the presence of a ketone compound whose solubility and solvation ability are high has the greatest affect, and next the presence of an alcohol compound has a large affect. It was understood by the investigation of the present inventors that due to the heat treatment in the various steps, most of the low-molecular-weight compound (volatile component such as a solvent) in the binder layer vaporizes, but it becomes easy for an alcohol compound whose boiling point is higher than that of a ketone compound to slightly remain, and the presence of the remaining slight alcohol compound, i.e., particularly the presence of low-molecular-weight methanol, remarkably lowers the anti-migration characteristics. These low-molecular-weight substances (low-molecular-weight compounds) represented by methanol become incorporated in the phenol resin particularly in the step of raw material synthesis, so that it is difficult to completely remove them from the phenol resin.

In the present embodiment, an amine-curable epoxy resin, and not a phenol resin, is used as the main component of the binder of the binder layer 16 of the fixing tape 9. That is, in the present embodiment, it is preferable for the binder layer 16 of the fixing tape 9 to include an amine-curable epoxy resin (as the main component), and for the content of the amine-curable epoxy resin to be at least 70% by weight. The binder layer 16 of the fixing tape 9 of the present embodiment does not substantially include phenol resin. Also, it is preferable for the binder layer 16 of the fixing tape 9 to include, in addition to the amine-curable epoxy resin, acrylonitrile butadiene rubber (NBR), and it is more preferable for the content of the acrylonitrile butadiene rubber (NBR) to be no less than 1% by weight and no more than 30% by weight.

There are no particular limitations on the epoxy resin (amine-curable epoxy resin) used in the binder layer 16 of the fixing tape 9, and various general epoxy resins can be used. Examples of particularly preferable epoxy resins include glycidyl ether epoxy resins represented by bisphenol A epoxy resin and not glycidyl ester epoxy resins. Examples of glycidyl epoxy resins include bisphenol A, bisphenol F, and novolac. Just one of these types may be used, or two or more of these types may be mixed together and used. Because there are many aliphatic epoxy resins and alicyclic epoxy resins whose viscosity is low, it is preferable to use them together with a viscosity-improving material (viscosity-improving agent). When there is insufficiency in the heat resistance just with a bifunctional epoxy resin, the heat resistance can be optionally improved by mixing together and using trifunctional or higher polyfunctional epoxy resins.

In contrast to the present embodiment, when a phenol-curable epoxy resin is used in the binder layer 16 of the fixing tape 9, there is the potential for a low-molecular-weight substance (low-molecular-weight compound) such as methanol to end up being included in the curing agent, for the low-molecular-weight substance to increase the ion mobility of the copper due to the aforementioned three causes (first, second, and third causes) to make it easy for migration of the copper to occur, and to lower the anti-migration characteristics. Also, in contrast to the present embodiment, when an anhydride-curable epoxy resin is used in the binder layer 16 of the fixing tape 9, it becomes easy for the viscosity of the binder layer 16 to become lower, and it is not easy to use this as the binder layer 16 of the fixing tape 9.

In the present embodiment, an amine curing agent is used for the curing agent of the epoxy resin used in the binder layer 16 of the fixing tape 9. That is, an amine-curable epoxy resin is used as the main component of the binder layer 16 of the fixing tape 9. Thus, the content of the low-molecular-weight substance (low-molecular-weight compound) in the base resin (epoxy resin) of the binder layer 16 of the fixing tape 9 can be reduced, and a viscosity suited for the binder layer 16 of the fixing tape 9 can be ensured. Of primary amine, secondary amine, and tertiary amine, tertiary amine is preferable as the amine curing agent used in the binder layer 16. Thus, a curing reaction at a low temperature (room temperature) can be prevented, and the binder layer 16 of the fixing tape 9 can be cured in a predetermined heating step, whereby the handling of the fixing tape 9 becomes easy. Particularly preferable examples of the amine curable agent used in the binder layer 16 include 2E4MZ: 2-ethyl-4-methylimidazole of tertiary amine and tris(dimethylaminomethyl)phenol or a trifluoride ethylamine complex of a Lewis acid complex.

Also, when the binder layer 16 of the fixing tape 9 is formed with only an epoxy resin, it is preferable for the binder layer 16 of the fixing tape 9 to include, in addition to the epoxy resin (amine-curable epoxy resin) serving as the base resin, NBR because there is insufficiency in the initial adhesion. Thus, the initial adhesion (adhesion prior to curing) of the binder layer 16 of the fixing tape 9 can be raised, and the adhesion of the fixing tape 9 to the lead frame 21 can be facilitated. By making the content of the NBR in the binder layer 16 of the fixing tape 9 no less than 1% by weight, the initial adhesion of the binder layer 16 of the fixing tape 9 can be adequately raised, and by making the content of the NBR in the binder layer 16 of the fixing tape 9 no more than 30% by weight, the durability of the binder layer 16 of the fixing tape 9 can be sufficiently ensured. If the content of the NBR is 31% by weight or greater, the viscosity of the binder layer 16 becomes too high, the adhesive layer ends up extending (pulling a string like candy), and the work of adhering the fixing tape 9 to the lead frame 21 becomes difficult. If the content of the NBR is less than 1% by weight, it becomes difficult to adhere the fixing tape 9 to the lead frame 21 because the binder layer 16 is not viscous. NBR whose ends have been denatured by a carboxyl group or an amino group may also be used.

It is more preferable for the content of the amine-curable epoxy resin in the binder layer 16 of the fixing tape 9 to be no less than 70% by weight. Thus, the viscosity of the binder layer 16 can be more adequately prevented from becoming too high. If the content of the amine-curable epoxy resin is no more than 69% by weight, the hardness of the binder layer 16 drops, and the work of adhering the fixing tape 9 to the lead frame 21 becomes difficult. If the content of the amine-curable epoxy resin is higher than 99% by weight, the binder layer 16 ends up being cured, and it becomes difficult to adhere the fixing tape 9 to the lead frame 21.

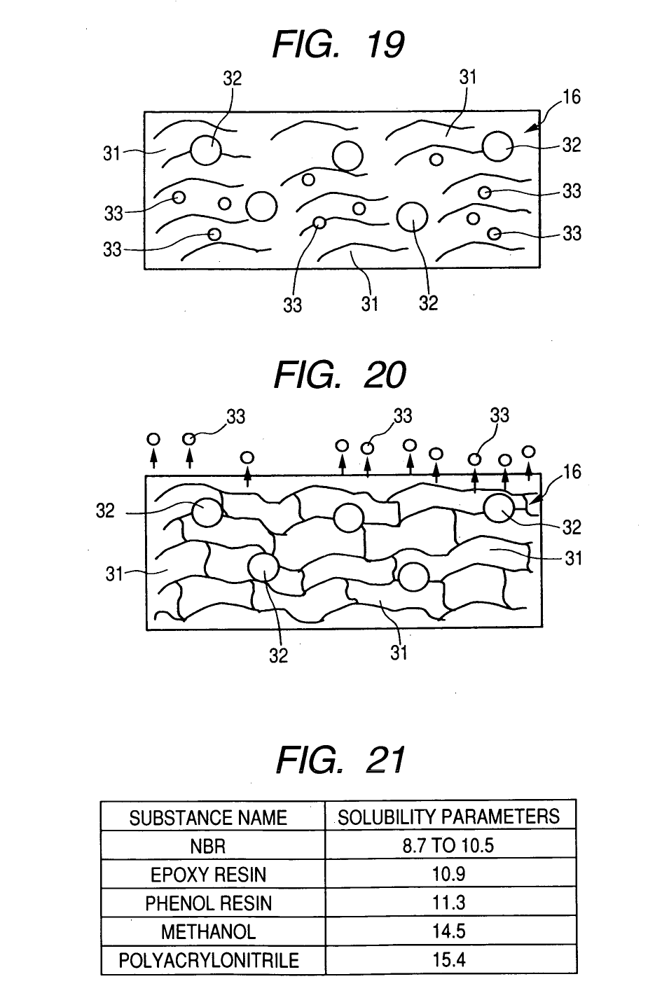

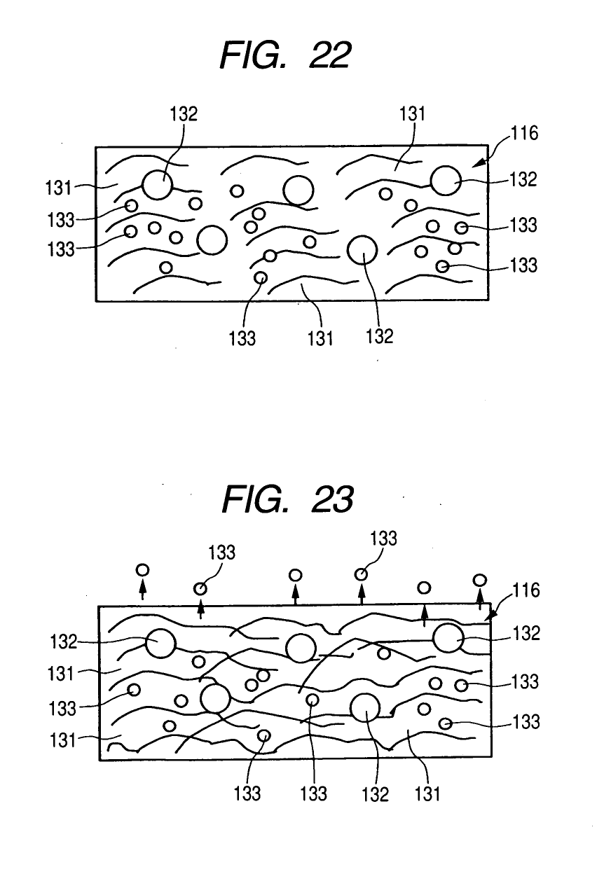

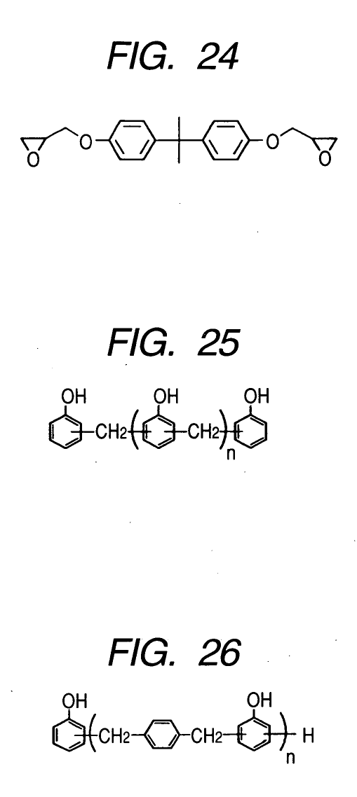

FIGS. 19 and 20 are explanatory diagrams schematically showing the state of the binder layer 16 of the fixing tape 9 of the present embodiment. FIG. 21 is an explanatory diagram (chart) showing solubility parameters of various substances. FIGS. 22 and 23 are explanatory diagrams schematically showing the state of the binder layer 116 of the fixing tape 109 of the comparative example. FIG. 24 is an explanatory diagram (chemical formula) showing the structure of bisphenol A epoxy resin as an example of the amine-curable epoxy resin, FIG. 25 is an explanatory diagram (chemical formula) showing the structure of an example of a phenol resin (formaldehyde phenol resin), and FIG. 26 is an explanatory diagram (chemical formula) showing another example of a phenol resin. FIGS. 19 and 22 correspond to a state where the fixing tapes 9 and 109 have been adhered to the lead frame 21 and the binder layers 16 and 116 have half-cured (the stage corresponding to FIGS. 8 and 9; before die bonding), and FIGS. 20 and 23 correspond to a state where the curing of the binder layers 16 and 116 of the fixing tape 9 and 109 has progressed due to heating (e.g., after the die bonding and wire bonding steps).

At the stage (before die bonding) corresponding to FIGS. 8 and 9 where the fixing tape 9 is adhered to the lead frame 21 and half-cured, as shown in FIG. 19, NBR (acrylonitrile butadiene rubber) 32 is present in a base resin 31 in the binder layer 16 of the fixing tape 9 of the present embodiment, and a miniscule amount of a low-molecular-weight volatile component 33 is also present. The base resin 31 comprises an epoxy resin and an amine curing agent. The low-molecular-weight volatile component 33 comprises methanol, acetone, and the like. Similarly, at the stage (same stage as in FIG. 19) where the fixing tape 109 of the comparative example is adhered to the lead frame 21 and half-cured, as shown in FIG. 22, NBR (acrylonitrile butadiene rubber) 132 is present in a base resin 131 in the binder layer 116 of the fixing tape 109 of the comparative example, and a miniscule amount of a low-molecular-weight volatile component 133 is also present. The base resin 131 comprises a phenol resin and a bismaleimide resin. Similar to the low-molecular weight volatile component 33, the low-molecular-weight volatile component 133 comprises methanol, acetone, and the like.

The common phenol resin shown in FIG. 25 is manufactured using phenol and formaldehyde as the raw materials. There are also resins that use a xylylene skeletal raw material as in the phenol resin shown in FIG. 26. In the phenol resin (formaldehyde phenol resin) of FIG. 25, water and methylol (low-molecular-weight volatile component) are generated in the reactive process (phenol resin generation process), and in the phenol resin of FIG. 26, methanol (low-molecular-weight volatile component) are generated in the reactive process (phenol resin generation process).

In contrast, the bisphenol A epoxy resin shown in FIG. 24 is manufactured using bisphenol A and epichlorohydrin as the raw materials. In the bisphenol A epoxy resin of FIG. 24, a low-molecular-weight volatile component such as methanol is not generated in the reactive process (epoxy resin generation process).

In this manner, the binder layer 116 of the fixing tape 109 of the comparative example includes a phenol resin in the base resin, methanol and methylol generated in the phenol resin generation process are present in the phenol resin, and as schematically shown in FIG. 22, there is a large amount of the low-molecular volatile component 133 in the binder layer 116. In contrast, the binder layer 16 of the fixing tape 9 of the present embodiment does not include a phenol resin but uses an amine-curable epoxy resin in the base resin 31, and in the epoxy resin generation process, a low-molecular-weight volatile component such as methanol is not generated, whereby the amount of the low-molecular-weight volatile component 33 present in the epoxy resin can be reduced, and as schematically shown in FIG. 19, the amount of the low-molecular-weight volatile component 33 in the binder layer 16 can be reduced. For this reason, in the state where the fixing tape has been adhered to the lead frame 21 and half-cured, as shown in FIGS. 19 and 22, the content of the low-molecular-weight volatile component 33 can be reduced more in the binder layer 16 of the fixing tape 9 of the present embodiment than in the binder layer 116 of the fixing tape 109 of the comparative example.

After the fixing tape has been adhered to the lead frame 21 and half-cured as in FIGS. 8 and 9, the lead frame 21 and the fixing tape 9 are heated as described above in the die bonding step of the semiconductor chip 3 of FIGS. 10 and 11 and the wire bonding step of FIGS. 12 and 13. Thus, the binder layer 16 of the fixing tape 9 is cured (the curing progresses, the cross-linking reaction progresses), but when the curing reaction of the base resin configuring the binder layer 16 progresses and the cross-linking density rises, as schematically shown in FIG. 20, the low-molecular-weight volatile component 33 enclosed inside is forced out and acts such that it is discharged to the outside of the binder layer 16. As shown in FIG. 21, the difference between the solubility parameters of the epoxy resin and the solubility parameters with methanol is relatively large, and the low-molecular-weight volatile component 33 such as methanol enclosed in the epoxy resin (base resin 31) whose solubility parameters are relatively small is easily dispersed and discharged to the outside of the binder layer 16 when the curing reaction of the epoxy resin progresses and the cross-linking density rises.

In contrast, as shown in FIG. 21, the solubility parameters of the phenol resin are close to those of a low-molecular-weight substance such as methanol in comparison to epoxy resin. That is, in comparison to the difference between the solubility parameters of epoxy resin and the solubility parameters with methanol, the difference between the solubility parameters of phenol resin and the solubility parameters with methanol is relatively small. For this reason, in the binder layer 116 of the fixing tape 109 of the comparative example including phenol resin in the base resin 131, the low-molecular-weight volatile component 133 such as methanol enclosed in the phenol resin (base resin 131) is not easily dispersed even if the curing reaction of the phenol resin progresses and the cross-linking density rises, and as schematically shown in FIG. 23, the low-molecular-weight volatile component 133 is not easily discharged to the outside of the binder layer 116 and remains in the binder layer 116.

If a low-molecular-weight compound (volatile component such as a solvent; low-molecular-weight volatile components 33 and 133) such as methanol is present in the binder layers 16 and 116, the ion mobility of copper increases due to the aforementioned first, second, and third causes, it becomes easy for migration of the copper to occur, and there is the potential to lower the anti-migration characteristics.

In the present embodiment, the binder layer 16 of the fixing tape 9 uses, in the base resin, the amine-curable epoxy resin where a low-molecular-weight volatile component such as methanol is not generated in the generation process, and the surface of the insulating film (tape base material layer 15) is coated (applied, formed) with a thermosetting binder to form (manufacture) the fixing tape 9. For this reason, the content of the low-molecular-weight volatile component 33 such as methanol in the initial state (stage where the binder layer 16 has not been cured) can be reduced, and the difference in the solubility parameters of the amine-curable epoxy resin of the base resin with the low-molecular-weight volatile component 33 such as methanol is relatively large, so that at the stage where the curing reaction of the binder layer 16 progresses, the low-molecular-weight volatile component 33 in the epoxy resin can be discharge to the outside of the binder layer 16. Consequently, in the present embodiment, the content of the low-molecular-weight volatile component 33 in the binder layer 16 after curing can be extremely reduced, and there is almost none of the low-molecular-weight volatile component 33 remaining (present) in the binder layer 16 after curing. Due to heating in the die bonding step of the semiconductor chip 3 and the wire bonding step of the bonding wires 6, the binder layer 16 is cured, almost none of the low-molecular-weight volatile component 33 is included in the binder layer 16, and thereafter the mold step is conducted and the sealing resin portion 2 is formed.

For this reason, even if a degradation test is conducted under the strict environmental degradation conditions of 150° C./100 V after the lead frame 21 is cut to manufacture the semiconductor device 1 after the formation of the sealing resin portion 2, copper migration is suppressed and the copper in the inner lead portions 12 can be prevented from being dispersed in the binder layer 16 of the fixing tape 9. That is, in the semiconductor device 1, because the abundance of a low-molecular-weight compound (volatile component such as a solvent) in the binder layer 16 of the fixing tape 9 can be extremely reduced, migration of the copper of the leads 4 resulting from the aforementioned first, second, and third causes can be suppressed or prevented, and the anti-migration characteristics can be improved. Thus, the dielectric breakdown resistance of the leads 4 of the semiconductor device 1 can be improved, and insulation failure between adjacent leads 4 of the semiconductor device 1 can be more adequately prevented. Also, because the content of the low-molecular-weight volatile component 33 present in the adhesive layer 16 in advance is a miniscule amount, even if out-gas is generated, it does not pollute the surfaces of the leads 4 and does not trigger defects in the connections of the bonding wires 6. Consequently, the reliability of the semiconductor device 1 can be improved, and the manufacturing yield of the semiconductor device can be improved.

The present invention will next be described specifically by way of examples, but the present invention is not limited only to these examples.

### EXAMPLE 1

A thermoplastic insulating film comprising polyimide was coated, to a thickness of 20 μm, with a binder material (corresponding to the binder configuring the binder layer 16) comprising 70% by weight of bisphenol A epoxy resin using 2E4MZ (2-ethyl-4-methylimidazole) as the curing agent and 30% by weight of NBR, to obtain a lead fixing tape (corresponding to the fixing tape 9).

### EXAMPLE 2

A thermoplastic insulating film comprising polyimide was coated, to a thickness of 20 μm, with a binder (corresponding to the binder configuring the binder layer 16) comprising 60% by weight of bisphenol A epoxy resin using 2E4MZ as the curing agent, 15% by weight of trifunctional glycidyl ether resin (triphenol glycidyl ether methane), and 25% by weight of NBR, to obtain a lead fixing tape (corresponding to the fixing tape 9).

### EXAMPLE 3

A thermoplastic insulating film comprising polyimide was coated, to a thickness of 20 μm, with a binder (corresponding to the binder configuring the binder layer 16) comprising 70% by weight of bisphenol F epoxy resin using 2E4MZ as the curing agent and 30% by weight of NBR, to obtain a lead fixing tape (corresponding to the fixing tape 9).

### COMPARATIVE EXAMPLE 1

A thermoplastic insulating film comprising polyimide was coated, to a thickness of 20 μm, with a binder (corresponding to the binder configuring the binder layer 116) comprising 45% by weight of bismaleimide resin, 30% by weight of amide imide resin, 25% by weight of NBR, and 10% by weight of phenol resin, to obtain a lead fixing tape (corresponding to the fixing tape 109).

Semiconductor devices were manufactured by conducting the same process as the manufacturing process of the semiconductor device 1 shown in FIGS. 6 to 17 using the lead fixing tapes of Examples 1 to 3 and Comparative Example 1 (the lead fixing tape 9 and the lead fixing tape 109).

That is, four types of semiconductor devices (semiconductor packages) of Examples 1 to 3 and Comparative Example 1 were manufactured by adhering and fixing the lead fixing tapes of Examples 1 to 3 and Comparative Example 1 to the inner lead portions 12 of the lead frames 21, mounting the semiconductor chips 3 on the tabs 7 of the lead frames 21 with the jointing material 11, electronically connecting the end portions of the inner lead portions 12 of the lead frames 21 and the electrodes 3a of the semiconductor chips 3 with the bonding wires 6, sealing the semiconductor chips 3 and the bonding wires 6 with the sealing resin portions 2, forming the outer shapes of the packages, cutting the lead frames 21, and forming the outer lead portions 13 led to the outside. The four types of semiconductor devices of Examples 1 to 3 and Comparative Example 1 had the same configurations (the same configuration as that of the semiconductor device 1) except that the materials of the binder layer 16 of the fixing tape 9 were different.

As a result of implementing gas analysis generated at the time of baking with a gas chromatography mass spectrometer (GC-MS) during the process of manufacturing the semiconductor devices of Examples 1 to 3 and Comparative Example 1, the generation of methanol was not observed in Examples 1 to 3, but methanol was detected in Comparative Example 1.

Next, a copper migration occurrence test was implemented for 100 hours under the conditions of 150° C./100 V. In the semiconductor devices of Examples 1 to 3, the growth of copper dendrites could not be observed at all after the test, but in Comparative Example 1, the growth of copper dendrites was clearly observed. That is, in the semiconductor devices of Examples 1 to 3, copper migration did not occur, but in the semiconductor device of Comparative Example 1, copper migration occurred.

In this manner, the fixing tape 9 of the present embodiment represented by Examples 1 to 3 suppressed the occurrence of out-gas resulting from heating and made it difficult for migration of the copper used in the lead frame (leads) to occur even under the strict environmental degradation conditions of 150° C./100 V. By manufacturing a semiconductor device using the fixing tape 9 of the present embodiment represented by Examples 1 to 3, it becomes possible to obtain a high-reliability semiconductor device.

### Second Embodiment

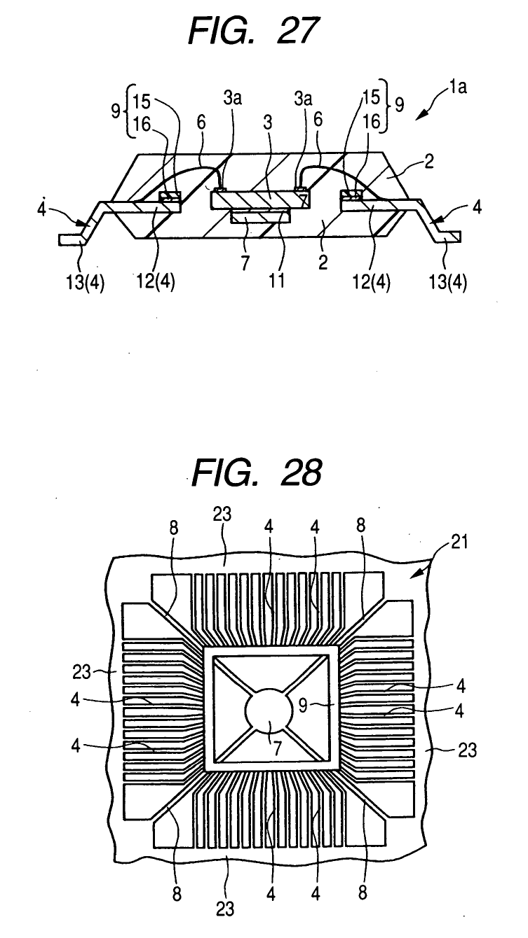

FIG. 27 is a cross-sectional view (side sectional view) of a semiconductor device 1a pertaining to a second embodiment of the invention, and corresponds to FIG. 3 of the first embodiment. FIG. 28 is a plan view of relevant portions during the manufacturing process of the semiconductor device 1a, and corresponds to FIG. 8 of the first embodiment.

In the first embodiment, the fixing tape 9 was somewhat to the outer side from the end portions of the inner lead portions 12 of the leads 4, and the ends of the bonding wires 6 were connected to the end portions of the inner lead portions 12 positioned at the inner side of the fixing tape 9. In contrast, in the present embodiment, as shown in FIGS. 27 and 28, the fixing tape 9 is adhered to the end portions of the inner lead portions 12, and the ends of the bonding wires 6 are connected to portions of the inner lead portions 12 positioned at the outer side of the fixing tape 9. In the present embodiment also, the same tape and binder layer as the fixing tape 9 and binder layer 16 used in the first embodiment as used for the fixing tape 9, and particularly the material for the binder layer 16. The remaining configuration of the semiconductor device 1a and the method of manufacturing the semiconductor device 1a are the same as that of the semiconductor device 1 and the method of manufacturing the semiconductor device 1 of the first embodiment, so description thereof will be omitted here.

By adhering the fixing tape 9 between the positions where the bonding wires 6 are connected to the upper surfaces 12a of the inner lead portions 12 and the electrodes 3a of the semiconductor device 1a, as in the second embodiment, the sagging (hanging) of the bonding wires 6 can be suppressed.

### Third Embodiment

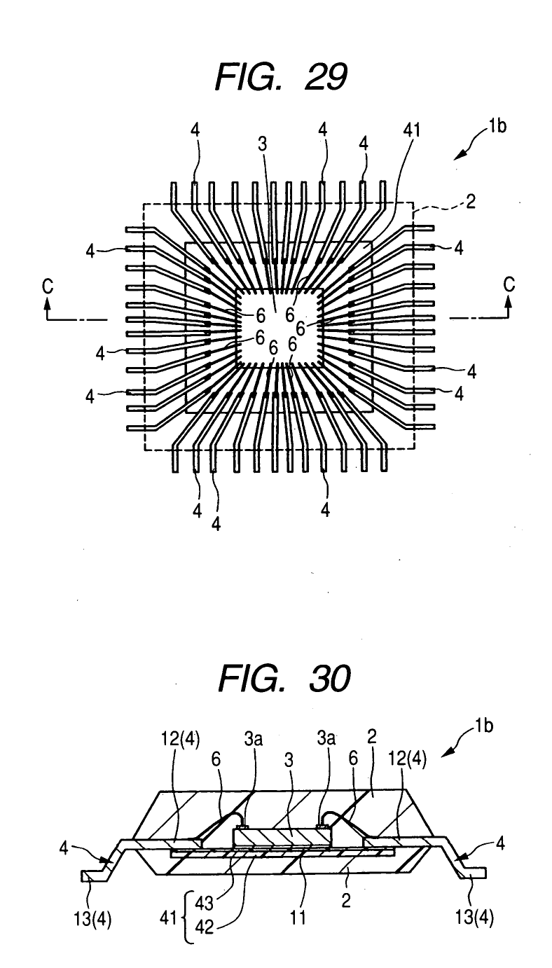

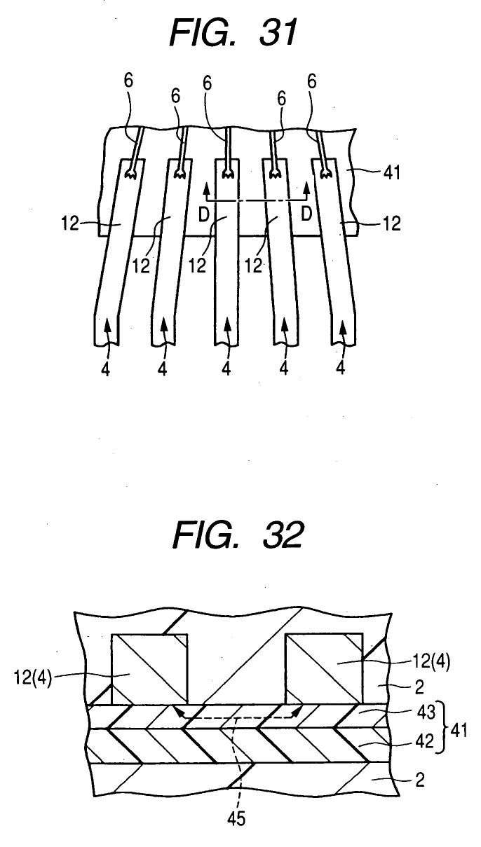

FIG. 29 is a plan (top) perspective view of a semiconductor device 1b pertaining to a third embodiment of the invention. FIG. 30 is a cross-sectional view (side sectional view), FIG. 31 is a plan view of relevant portions (plan perspective view), and FIG. 32 is a cross-sectional view of relevant portions (partially enlarged cross-sectional view). FIG. 29 corresponds to a plan (top) view when seen through the sealing resin portion 2, and FIG. 31 corresponds to a plan view of relevant portions (partially enlarged plan view) when seen through the sealing resin portion 2. The cross section along line C-C of FIG. 29 substantially corresponds to FIG. 30. The cross section along line D-D of FIG. 31 substantially corresponds to FIG. 32.

In the first embodiment, the semiconductor chip 3 was mounted on the tab 7 to which the leads 4 were not connected. In contrast, in the present embodiment, as shown in FIGS. 29 to 32, the semiconductor chip 3 is mounted on a heat spreader 41 adhered to the plural leads 4, instead of the tab 7.

The heat spreader 41 comprises a heat spreader base material layer 42 and a binder layer 43 on the heat spreader base material layer 42. The heat spreader base material 42 comprises a material with a low thermal conductivity, such as a metal (e.g., copper foil or a copper plate). The heat spreader 41 is adhered (bonded) in the vicinity of the end portions of the inner lead portions 12 of the plural leads 4 such that its binder layer 43 side contacts (faces) the inner lead portions 12. In the case of FIGS. 29 to 32, the (binder layer 43 of the) heat spreader 41 is adhered to the lower surfaces of the inner lead portions 12. The remaining configuration of the semiconductor device 1b is substantially the same as that of the semiconductor device 1 of the first embodiment. That is, the plural electrodes 3a of the semiconductor chip 3 mounted on the heat spreader 41 via the jointing material 11 and the plural inner lead portions 12 are electrically bonded via the plural bonding wires 6, and the semiconductor chip 3, the bonding wires 6, the inner lead portions 12 and the heat spreader 41 are sealed by the sealing resin portion 2.

By using a conductor such as metal that has excellent thermal conductivity as the heat spreader base material layer 42, the heat from the semiconductor chip 3 can be dissipated to the mounting substrate (not shown) mounting the semiconductor device 1b via the heat spreader 41 and the leads 4. That is, the heat spreader 41 can function as the mounting portion for the semiconductor chip 3 (chip mounting portion) and a heat-dissipating member. As another mode, an insulator (e.g., tape, insulating film, base plate) can also be used for the heat spreader base material layer 42. When the heat spreader base material layer 42 is formed by an insulating layer, the heat spreader 41 does not function as a heat-dissipating member, but can function as a mounting portion for the semiconductor chip 3 (chip mounting portion).

In the present embodiment also, the same material as that of the binder layer 16 of the fixing tape 9 of the first embodiment is used for the material of the binder layer 43 of the heat spreader 41: That is, the main component of the binder of the binder layer 43 of the heat spreader 41 is an amine-curable epoxy resin and not a phenol resin. Consequently, the binder layer 43 of the heat spreader 41 is a thermosetting binder and does not substantially include phenol resin, and it is more preferable for the content of the amine-curable epoxy resin to be at least 70% by weight. It is also preferable for the binder layer 43 of the heat spreader 41 to include acrylonitrile butadiene rubber (NBR) in addition to the amine-curable epoxy resin. The materials that are particularly preferable for the epoxy resin and curing agent used in the binder layer 43 of the heat spreader 41 and the preferable range of the content of the NBR are the same as those for the binder layer 16 of the fixing tape 9 of the first embodiment, so description thereof will be omitted here.

Next, the manufacturing process of the semiconductor device 1b of the present embodiment will be described.

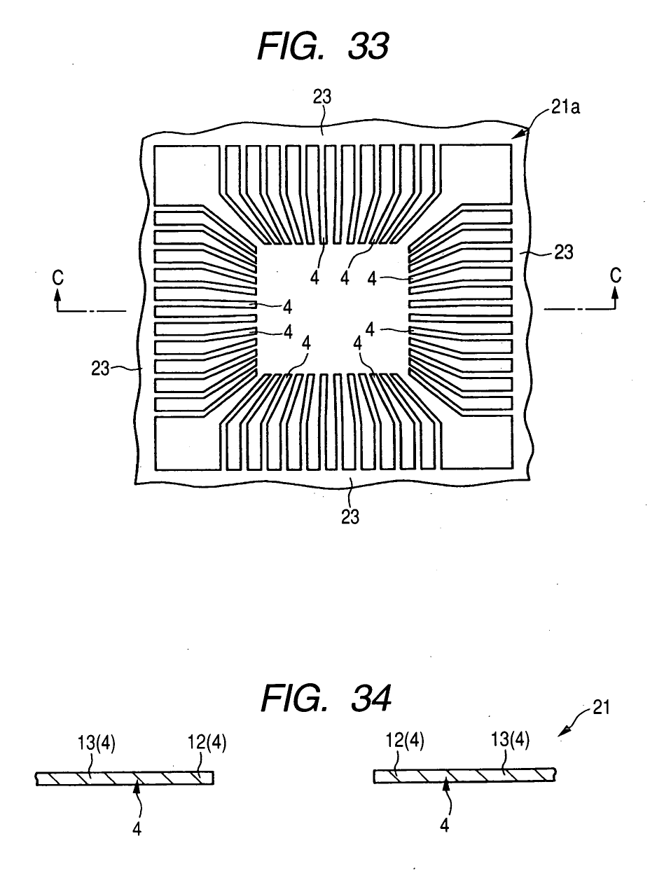

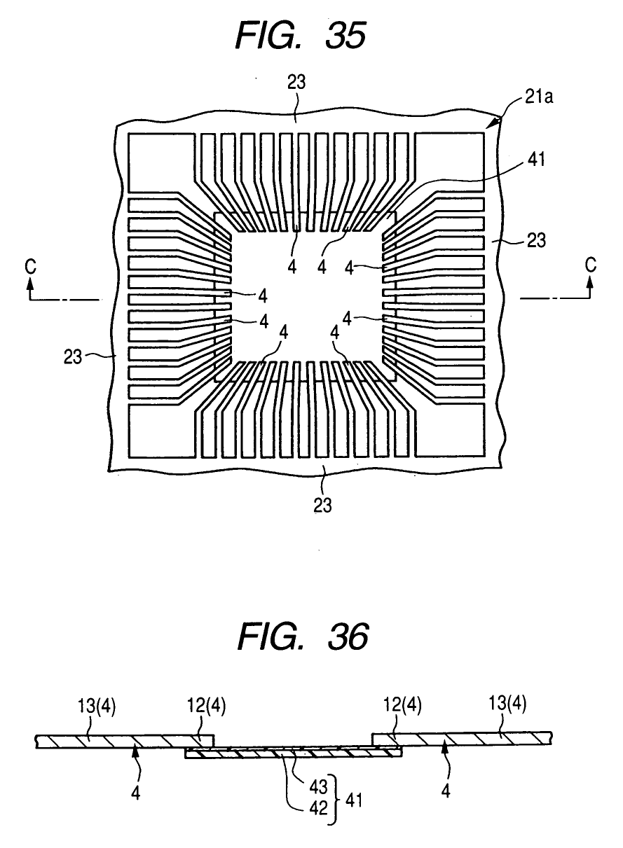

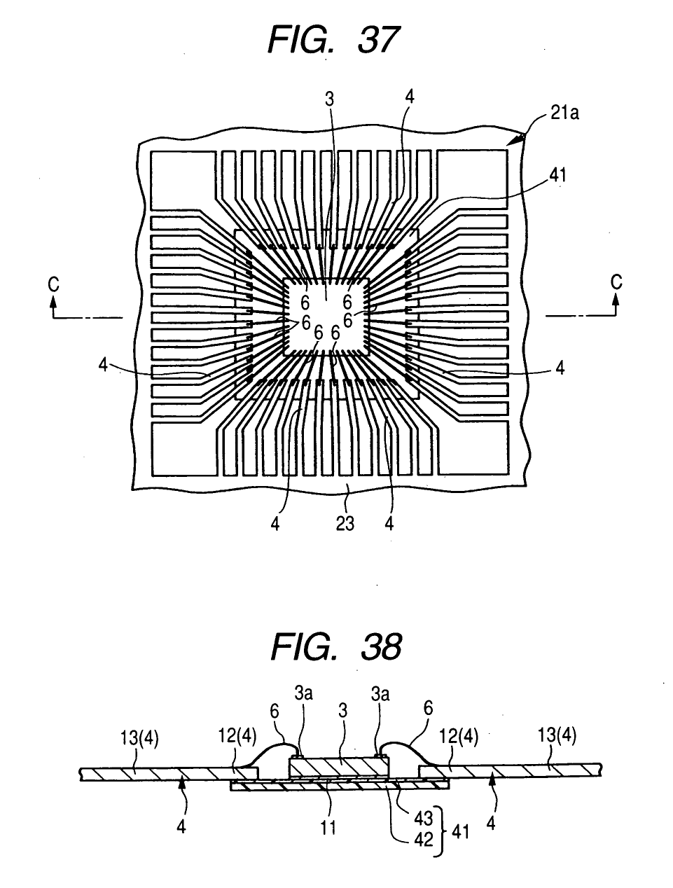

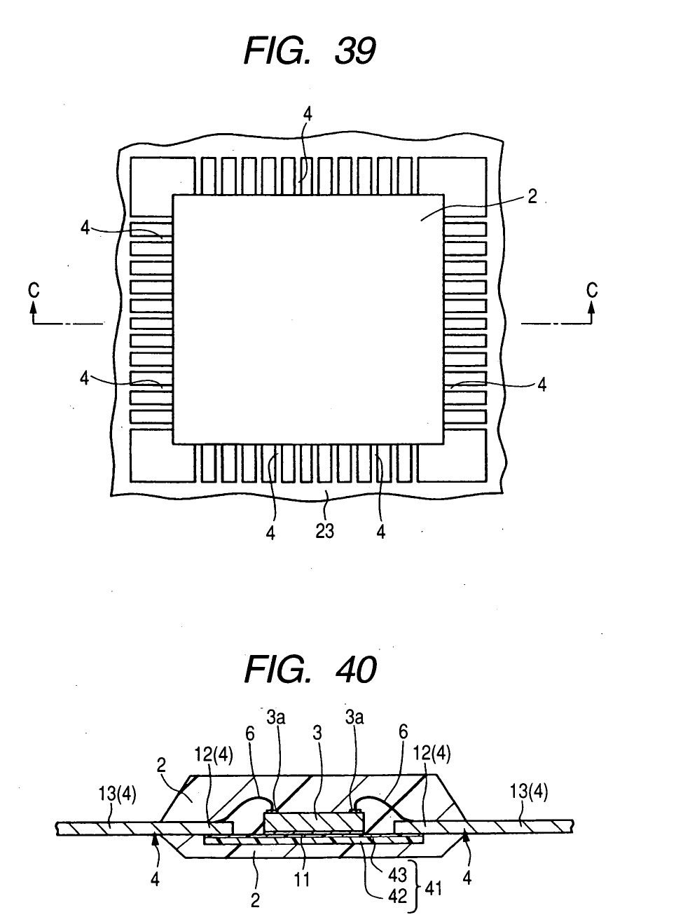

FIGS. 33 to 40 are plan views (plan views of relevant portions) or cross-sectional views (cross-sectional views of relevant portions) showing the manufacturing process of the semiconductor device 1b of the present embodiment. Of FIGS. 33 to 40, FIGS. 33, 35, 37 and 39 are plan views (plan views of relevant portions), and FIGS. 34, 36, 38 and 40 are cross-sectional views (cross-sectional views of relevant portions). FIGS. 33 and 34 correspond to the same process stage, FIGS. 35 and 36 correspond to the same process stage, FIGS. 37 and 38 correspond to the same process stage, and FIGS. 39 and 40 correspond to the same process stage. The cross-sectional views of FIGS. 34, 36, 38 and 40 show a cross section along line C-C of FIG. 29, i.e., the same cross section as in FIG. 30. Line C-C is shown at positions in FIGS. 33, 35, 37 and 39 corresponding to the position of line C-C in FIG. 29. A region corresponding to one semiconductor package of the lead frame 21a is shown in the plan views of FIGS. 33, 35, 37 and 39.

In manufacturing the semiconductor device 1b, as shown in FIGS. 33 and 34, first, the lead frame 21a is prepared. The lead frame 21a has substantially the same configuration as that of the lead frame 21 of the first embodiment, except that the tab 7 and the dangling leads 8 are not disposed, and comprises a conductor material including copper or copper like a copper alloy, for example. For the lead frame 21a, an etching frame comprising a metal plate (copper plate or copper alloy plate) that has been etched, or a stamping frame (press frame) comprising a metal plate (copper plate or copper alloy plate) that has been stamped (pressed), can be used.

When the heat spreader 41 is to be adhered to the lower surfaces of the inner lead portions 12 of the leads 4 of the lead frame 21a, the heat spreader 41 is adhered to the lower surfaces of the inner lead portions 12 of the leads 4 such that the binder layer 43 side contacts (faces) the lower surfaces of the inner lead portions 12 of the leads 4. That is, the heat spreader 41 including the binder layer 43 is adhered via the binder layer 43 to the lower surfaces of the inner lead portions 12 of the plural leads 4 of the lead frame 21a. For example, the lower surfaces of the inner lead portions 12 can be adhered and fixed to the binder layer 43 of the heat spreader 41 by etching or die-pressing a metal plate (copper plate or copper alloy plate) into a predetermined shape to manufacture the lead frame 21a, heating the lead frame 21a to a predetermined temperature (e.g., about 150 to about 200° C.), and then pressing (pressure-adhering) the heat spreader 41 onto the lower surfaces of the inner lead portions 12 of the leads 4 for a predetermined amount of time. Because the inner lead portions 12 of the plural leads 4 are fixed by the heat spreader 41, the tape 9 for fixing the inner lead portions 12 does not have to be separately used.

After the lead frame 21a, where the heat spreader 41 is adhered to the plural leads 4, has been prepared in this manner, the semiconductor device is manufactured (assembled) in substantially the same manner as in the first embodiment.

That is, as shown in FIGS. 37 and 38, a die bonding step is conducted to mount the semiconductor chip 3 on the heat spreader 41. In this die bonding step, the semiconductor chip 3 is adhered (bonded) via the jointing material 11 comprising silver (Ag) paste or the like onto the heat spreader 41.

Next, a wire bonding step is conducted to electrically connect, via the plural bonding wires 6, the plural electrodes 3a of the semiconductor chip 3 to the upper surfaces 12a of the inner lead portions 12 of the plural leads 4 of the lead frame 21a.

Next, as shown in FIGS. 39 and 40, a mold step (e.g., a transfer mold step) is conducted to seal the semiconductor chip 3 and the bonding wires 6 with the sealing resin portion 2. In the mold step, the inner lead portions 12 of the leads 4 of the lead frame 21a and the heat spreader 41 are also sealed by the sealing resin portion 2.

Next, the lead frame 21a is cut at predetermined positions and divided into pieces. After the lead frame 21a has been cut, the outer lead portions 13 of the leads 4 protruding from the sealing resin portion 2 are molded. In this manner, semiconductor devices (semiconductor packages) divided into pieces, i.e., the semiconductor devices 1b shown in FIGS. 29 to 32, are formed. After the sealing resin portion 2 has been formed, plating can be conducted before or after the lead frame 21a is cut, so that a plating layer (e.g., a solder plating layer) is formed on the outer lead portions 13 of the semiconductor device 1b.

Thereafter, a marking step and a sorting step are conducted with respect to the semiconductor devices 1b, and semiconductor devices 1b sorted as good products in the sorting step are shipped as products (semiconductor packages).

In the present embodiment, the heat spreader 41 is adhered to the inner lead portions 12 of the plural leads 4 by the binder layer 43. For this reason, when a phenol resin is used for the material of the binder layer 43 in contrast to the present embodiment, there is the potential for migration of the copper in the inner lead portions 12 to occur, and for the copper in the inner lead portions 12 to disperse through the binder layer 43 and lower the reliability of the semiconductor device, as described in the first embodiment. For example, there is the potential for migration of the copper (dispersion of the copper through the binder layer 43) to occur in a path 45 schematically represented by the dotted line in FIG. 32 and lower the dielectric breakdown resistance of the leads 4 of the semiconductor device 1b.

In the present embodiment, the migration of the copper in the inner lead portions 12 (dispersion through the binder layer 43) can be suppressed or prevented by using the same material as that of the binder layer 16 of the fixing tape 9 of the first embodiment for the material of the binder layer 43 of the heat spreader 41. Even if a degradation test is conducted under the strict environmental degradation conditions of 150° C./100 V, the copper in the inner lead portions 12 can be prevented from being dispersed through the binder layer 43 of the heat spreader 41. Because the migration of the copper in the leads 4 can be suppressed or prevented and the anti-migration characteristics can be improved, the dielectric breakdown resistance of the leads 4 of the semiconductor device 1b can be improved, and insulation failure between adjacent leads 4 of the semiconductor device 1b can be more adequately prevented. Also, the generation of a large amount of out-gas from the (binder layer 43 of the) heat spreader 41 due to heating can be suppressed or prevented. Consequently, the reliability of the semiconductor device can be improved, and the manufacturing yield of the semiconductor device can be improved.

### Fourth Embodiment

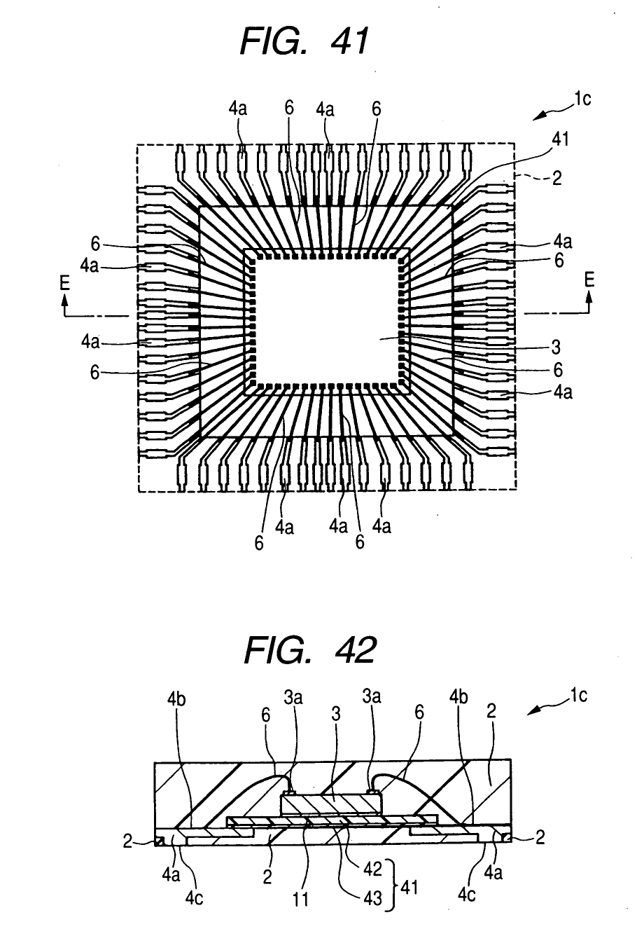

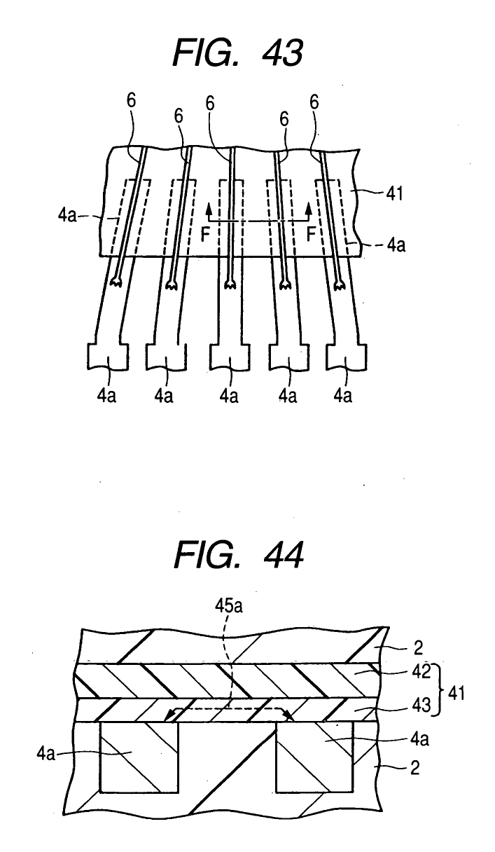

FIG. 41 is a plan (top) perspective view of a semiconductor device 1c pertaining to a fourth embodiment of the invention. FIG. 42 is a cross-sectional view (side sectional view), FIG. 43 is a plan view of relevant portions (plan perspective view), and FIG. 44 is a cross-sectional view of relevant portions (partially enlarged cross-sectional view). FIG. 41 corresponds to a plan (top) view when seen through the sealing resin portion 2, and FIG. 43 corresponds to a plan view of relevant portions (partially enlarged plan view) when seen through the sealing resin portion 2. The cross section along line E-E of FIG. 41 substantially corresponds to FIG. 42, and the cross section along line F-F of FIG. 43 substantially corresponds to FIG. 44.

The present embodiment is a quad flat non-leaded package (QFN) semiconductor device 1c.

In the semiconductor device 1c shown in FIGS. 41 to 44, leads 4a (corresponding to the leads 4 of the first to third embodiments) function both as inner leads embedded in the sealing resin portion 2 and as outer leads exposed to the undersurface of the sealing resin portion 2. That is, ends of the bonding wires 6, which are sealed by the sealing resin portion 2, are connected (bonded) to upper surfaces 4b of the leads 4a that can function as bonding portions of the leads 4a, and lower portion exposed surfaces 4c, which are exposed portions on the lower surfaces of the leads 4a that can function as external connection-use terminal portions (external terminals) of the semiconductor device 1c, are exposed to the undersurface 2b of the sealing resin portion 2. The lower portion exposed surfaces 4c have a substantially rectangular shape or a substantially square shape. As the external end portions of the leads 4a, cut surfaces of the leads 4a are exposed at the side surface of the sealing resin portion 2. The spaces between adjacent leads 4a are filled with the material configuring the sealing resin portion 2 such that adjacent leads 4a do not come into contact with each other. A plating layer is formed on the lower portion exposed surfaces 4c of the leads 4a exposed at the undersurface 2b of the sealing resin portion 2, but in order to facilitate understanding, illustration of the plating layer is omitted. The material and the like of the leads 4a are the same as those of the leads 4 of the first to third embodiments.

In the present embodiment also, similar to the third embodiment, the semiconductor chip 3 is mounted on the heat spreader 41 adhered to the plural leads 4a. The heat spreader 41 comprises the heat spreader base material layer 42 and the binder layer 43 on the heat spreader base material layer 42. The materials of the heat spreader base material layer 42 and the binder layer 43 are the same as those in the third embodiment, so description thereof will be omitted here.

The heat spreader 41 is adhered (bonded) in the vicinity of the end portions (inner end portions) of the plural leads 4a such that its binder layer 43 side contacts (faces) the inner lead portions 12. In the cases of FIGS. 41 to 44, the (binder layer 43 of the) heat spreader 41 is adhered to the upper surfaces of the end portions of the leads 4a. The remaining configuration of the semiconductor device 1c is substantially the same as that of the semiconductor device 1b of the third embodiment. That is, the plural electrodes 3a of the semiconductor chip 3 mounted on the heat spreader 41 via the jointing material 11 and the upper surfaces of the plural leads 4a are electrically bonded via the plural bonding wires 6, and the semiconductor chip 3, the bonding wires 6, the leads 4a and the heat spreader 41 are sealed by the sealing resin portion 2.

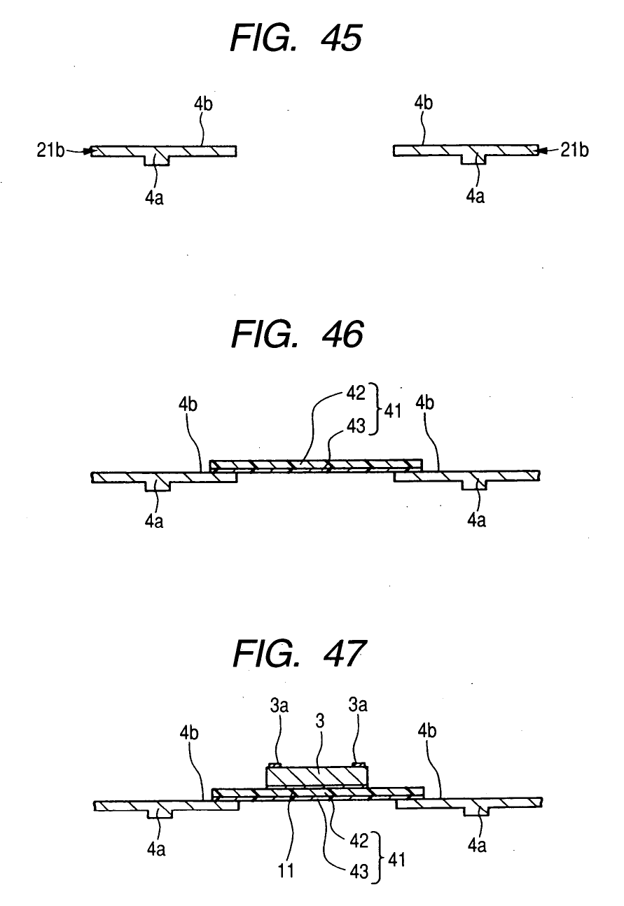

The semiconductor device 1c of the present embodiment can be manufactured in substantially the same manner as the semiconductor device 1b of the third embodiment. FIGS. 45 to 49 are cross-sectional views (cross-sectional views of relevant portions) showing the manufacturing process of the semiconductor device 1c of the present embodiment. A cross section of the region substantially corresponding to FIG. 42 is shown in the cross-sectional views of FIGS. 45 to 49.

In manufacturing the semiconductor device 1c, first, as shown in FIG. 45, a lead frame 21b is prepared. The lead frame 21b has substantially the same configuration as that of the lead frame 21a of the third embodiment, except for the shape of the leads 4a, and comprises a conductor material including copper or copper like a copper alloy, for example. For the lead frame 21b, an etching frame comprising a metal plate (copper plate or copper alloy plate) that has been etched, or a stamping frame (press frame) comprising a metal plate (copper plate or copper alloy plate) that has been stamped (pressed), can be used.

Next, as shown in FIG. 46, the heat spreader 41 is adhered to the upper surfaces of the end portions of the leads 4a of the lead frame 21b.

When the heat spreader 41 is to be adhered to the upper surfaces of the end portions of the leads 4a of the lead frame 21b, the heat spreader 41 is adhered to the upper surfaces of the end portions of the leads 4a such that the binder layer 43 side contacts (faces) the upper surfaces 4b of the leads 4a. That is, the heat spreader 41 including the binder layer 43 is adhered via the binder layer 43 to the upper surfaces of the end portions of the plural leads 4a of the lead frame 21b. For example, the lower surfaces of the end portions of the leads 4a can be adhered and fixed to the binder layer 43 of the heat spreader 41 by etching or die-pressing a metal plate (copper plate or copper alloy plate) into a predetermined shape to manufacture the lead frame 21b, heating the lead frame 21b to a predetermined temperature (e.g., about 150 to about 200° C.), and then pressing (pressure-adhering) the heat spreader 41 onto the upper surfaces of the end portions of the leads 4a for a predetermined amount of time. Because the end portions of the plural leads 4a are fixed by the heat spreader 41, the fixing tape 9 for the leads does not have to be separately used.

After the lead frame 21b, where the heat spreader 41 is adhered to the plural leads 4a, has been prepared in this manner, the semiconductor device is manufactured (assembled) in substantially the same manner as in the third embodiment.

That is, as shown in FIG. 47, a die bonding step is conducted to mount the semiconductor chip 3 on the heat spreader 41. In this die bonding step, the semiconductor chip 3 is adhered (bonded) via the jointing material 11 comprising silver (Ag) paste or the like onto the heat spreader 41.

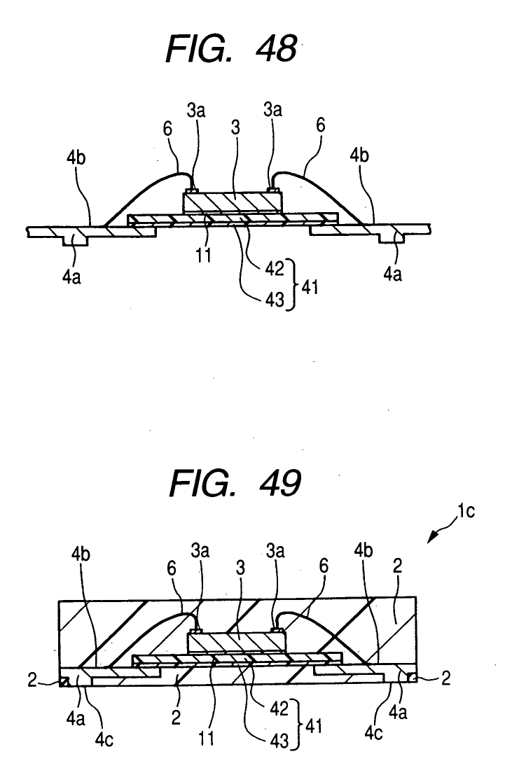

Next, as shown in FIG. 48, a wire bonding step is conducted to electrically connect, via the plural bonding wires 6, the plural electrodes 3a of the semiconductor chip 3 to the upper surfaces 12a of the plural leads 4a of the lead frame 21b.

Next, as shown in FIG. 49, a mold step (e.g., a transfer mold step) is conducted to seal the semiconductor chip 3 and the bonding wires 6 with the sealing resin portion 2. In the mold step, the leads 4a of the lead frame 21b and the heat spreader 41 are also sealed by the sealing resin portion 2.

Next, the lead frame 21b is cut at predetermined positions and divided into pieces. Because the portions of the lead frame 21b exposed from the side surface of the sealing resin 2 are removed from the sealing resin portion 2, the leads 4a do not protrude from the side surface of the sealing resin portion 2. In this manner, semiconductor devices (semiconductor packages) 1c divided into pieces, i.e., the QFN semiconductor devices 1c, are obtained. After the sealing resin portion 2 has been formed, plating can be conducted before or after the lead frame 21b is cut, so that a plating layer (e.g., a solder plating layer) is formed on the lower portion exposed surfaces 4c of the leads 4a exposed at the undersurface 2b of the sealing resin portion 2.

Thereafter, a marking step and a sorting step are conducted with respect to the semiconductor devices 1c, and semiconductor devices 1c sorted as good products in the sorting step are shipped as products (semiconductor packages).

In the present embodiment also, effects that are substantially the same as those of the first to third embodiments can be obtained.

That is, in the present embodiment, the heat spreader 41 is adhered to the end portions of the plural leads 4a by the binder layer 43. For this reason, when a phenol resin is used for the material of the binder layer 43 in contrast to the present embodiment, there is the potential for migration of the copper in the lead 4a to occur, and for the copper in the leads 4a to disperse through the binder layer 43 and lower the reliability of the semiconductor device, as described in the first embodiment. For example, there is the potential for migration of the copper (dispersion of the copper through the binder layer 43) to occur in a path 45a schematically represented by the arrow in FIG. 44 and lower the dielectric breakdown resistance of the leads 4a of the semiconductor device 1c.

In the present embodiment, the migration of the copper in the leads 4a (dispersion through the binder layer 43) can be suppressed or prevented by using the same material as that of the binder layer 16 of the fixing tape 9 of the first embodiment for the material of the binder layer 43 of the heat spreader 41. Even if a degradation test is conducted under the strict environmental degradation conditions of 150° C./100 V, copper migration is suppressed, and the copper in the leads 4a can be prevented from being dispersed through the binder layer 43 of the heat spreader 41. Because the migration of the copper in the leads 4a can be suppressed or prevented and the anti-migration characteristics can be improved, the dielectric breakdown resistance of the leads 4a of the semiconductor device 1c can be improved, and insulation failure between adjacent leads 4a of the semiconductor device 1c can be more adequately prevented. Also, the generation of a large amount of out-gas from the (binder layer 43 of the) heat spreader 41 due to heating can be suppressed or prevented. Consequently, the reliability of the semiconductor device can be improved, and the manufacturing yield of the semiconductor device can be improved.

### Fifth Embodiment

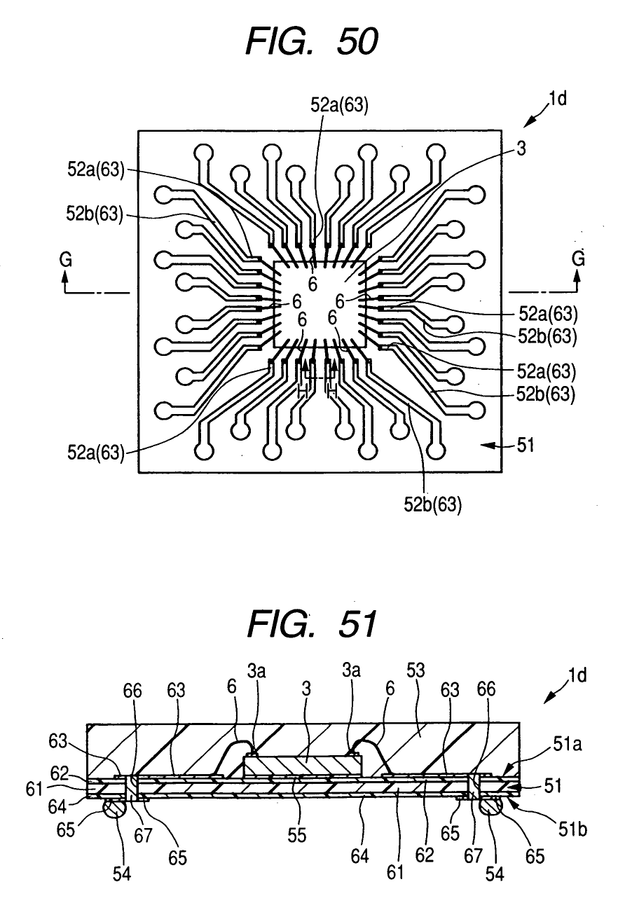

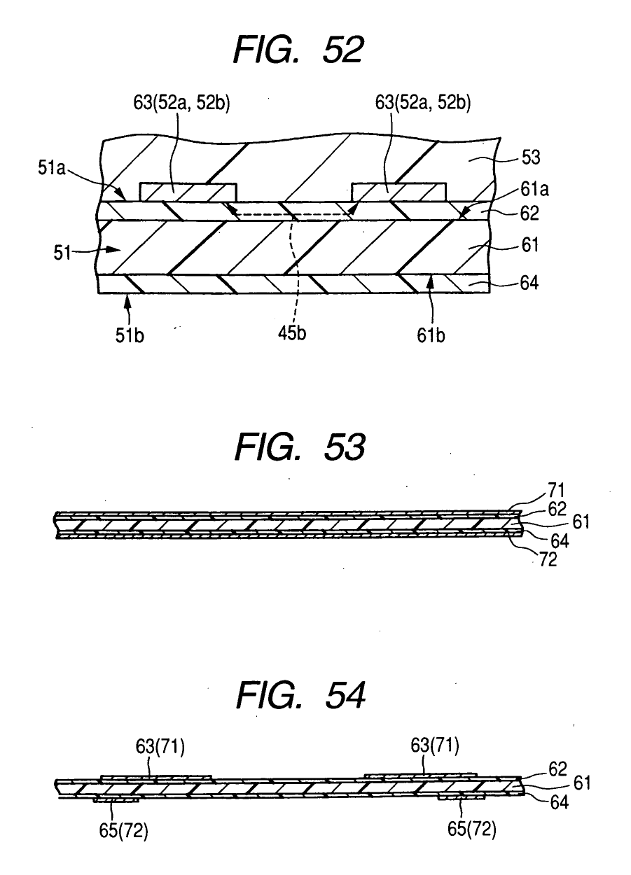

FIG. 50 is a plan (top) perspective view of a semiconductor device 1d pertaining to a fifth embodiment of the invention. FIG. 51 is a cross-sectional view (side sectional view), and FIG. 52 is a cross-sectional view of relevant portions (partially enlarged cross-sectional view) FIG. 50 corresponds to a plan (top) view when seen through the sealing resin portion 2. The cross section along line G-G of FIG. 50 substantially corresponds to FIG. 51, and the cross section along line H-H of FIG. 50 substantially corresponds to FIG. 52.

The present embodiment is a semiconductor package manufactured using a wiring board, and is a ball grid array (BGA) or chip size package (CSP) semiconductor device 1d.

The semiconductor device 1d of the present embodiment shown in FIGS. 50 to 52 includes: the semiconductor chip 3; a wiring board (tape board) 51 that supports or mounts the semiconductor chip 3; the plural bonding wires 6 that electrically connect the plural electrodes 3a on the surface of the semiconductor chip 3 to plural connection terminal portions 52a of the wiring board 51 corresponding to the electrodes 3a; a sealing resin portion (sealing portion, sealing body) 53 that covers an upper surface 51a of the wiring board 51 including the semiconductor chip 3 and the bonding wires 6; and plural solder balls (ball electrodes, protruding electrodes, electrodes, external terminals) 54 disposed in an area array arrangement, for example, as external terminals on a lower surface 51b of the wiring board 51.

The semiconductor chip 3 is disposed on the upper surface (chip support surface) 51a of the wiring board 51 such that its surface (the side on which the semiconductor element is formed) faces upward, and the undersurface (the opposite side of the side on which the semiconductor element is formed) of the semiconductor chip 3 is adhered and fixed, via a binder (die bond material, jointing material) 55, to the upper surface 51a of the wiring board 51. The binder 55 is an insulating binder, but a conductive paste material (e.g., silver paste) or the like may be used.

The wiring board 51 includes: an insulating base material layer (base film, insulating base plate, core material) 61; a conductor layer (conductor pattern, conductor film pattern, wiring layer, copper layer) 63 formed (adhered) via a binder layer 62 on an upper surface 61a of the base material layer 61; and a conductor layer (conductor pattern, conductor film pattern, wiring layer, copper layer) 65 formed (adhered) via a binder layer 64 on a lower surface 61b of the base material layer 61. A solder resist layer (not shown) can also be formed on the upper surface 51a and the lower surface 51b of the wiring board 51 so as to cover part of the conductor layers 63 and 65 and expose the other part. As another mode, the wiring board 51 can also be formed by a multilayer wiring board in which plural insulating layers and plural wiring layers are laminated.

The base material layer 61 of the wiring board 51 comprises an insulator material, and can be formed by polyimide (polyimide film) or the like. The conductor layers 63 and 65 are patterned, and are conductor patterns that become the terminals or the wiring (wiring layers) of the wiring board 51. The conductor layers 63 and 65 comprise a conductive material including copper or a copper like a copper alloy, and can be formed by copper thin films (or copper alloy thin films) such as copper foil. The connection terminal portions (electrodes, bonding pads, pad electrodes) 52a for connecting the bonding wires 6 and wirings (wiring portions, pullout wirings, pull-around wirings) 52b connected to the connection terminal portions 52a are plurally formed by the conductor layer 63 at the upper surface 51a side of the wiring board 51. Conductive land portions (electrodes, pads, terminals) for connecting the solder balls 54 are plurally formed by the conductor layer 65 at the lower surface 51b side of the wiring board 51. Plural open portions (through holes, via holes, penetration holes) 66 are formed in the base material layer 61, and conductor layer 67 is also formed on the side walls of the open portions 66. The plural solder balls 54 are bonded (solder-connected) and electrically connected to the plural conductive land portions comprising the conductor layer 65 at the lower surface 51b side of the wiring board 51. For this reason, the plural solder balls 54 are disposed in an array, for example, on the lower surface 51b of the wiring board 51, such that the solder balls 54 can function as external terminals (external connection terminals) of the semiconductor device 1d.

The plural electrodes 3a of the semiconductor chip 3 and the plural connection terminal portions 52a formed by the conductor layer 63 of the upper surface 51a of the wiring board 51 are electrically connected via the plural bonding wires 6. The connection terminal portions 52a (portions connected to the bonding wires 6) of the semiconductor layer 63 of the upper surface 51a of the wiring board 51 are electrically connected, via the wirings 52b comprising the semiconductor layer 63 of the upper surface 51a of the wiring board 51, the conductor layer 67 on the side walls of the open portions 66 and the conductor layer 65 of the lower surface 51b of the wiring board 51, to the conductive land portions comprising the semiconductor layer 65 of the lower surface 51b of the wiring board 51 and to the solder balls 54 bonded to the conductive land portions. Consequently, the plural electrodes 3a of the semiconductor chip 3 are electrically connected to the conductor layer 63 of the wiring board 51 via the plural bonding wires 6 and are electrically connected to the plural solder balls 54 via the conductor layers 63, 65 and 67 of the wiring board 51.

The sealing resin portion 53 comprises a resin material such as a thermosetting resin material, and can also include a filler. For example, the sealing resin portion 53 can be formed using an epoxy resin including a filler. The semiconductor chip 3 and the bonding wires 6 are sealed and protected by the sealing resin portion 53.

In the present embodiment also, the same material as that of the binder layer 16 of the fixing tape 9 of the first embodiment is used for the material of the binder layer 62 that adheres the conductor layers 63 and 65 of the wiring board 51 to the insulating base material layer 61. That is, the main component of the binder of the binder layer 62 of the wiring board 51 is an amine-curable epoxy resin and not a phenol resin. Consequently, the binder layer 62 of the wiring board 51 is a thermosetting binder and does not substantially include phenol resin, and it is more preferable for the content of the amine-curable epoxy resin to be at least 70% by weight. It is also preferable for the binder layer 62 of the wiring board 51 to include acrylonitrile butadiene rubber (NBR) in addition to the amine-curable epoxy resin. The materials that are particularly preferable for the epoxy resin and curing agent used in the binder layer 62 of the wiring board 51 and the preferable range of the content of the NBR are the same as those in the case of the binder layer 16 of the fixing tape 9 of the first embodiment, so description thereof will be omitted here.

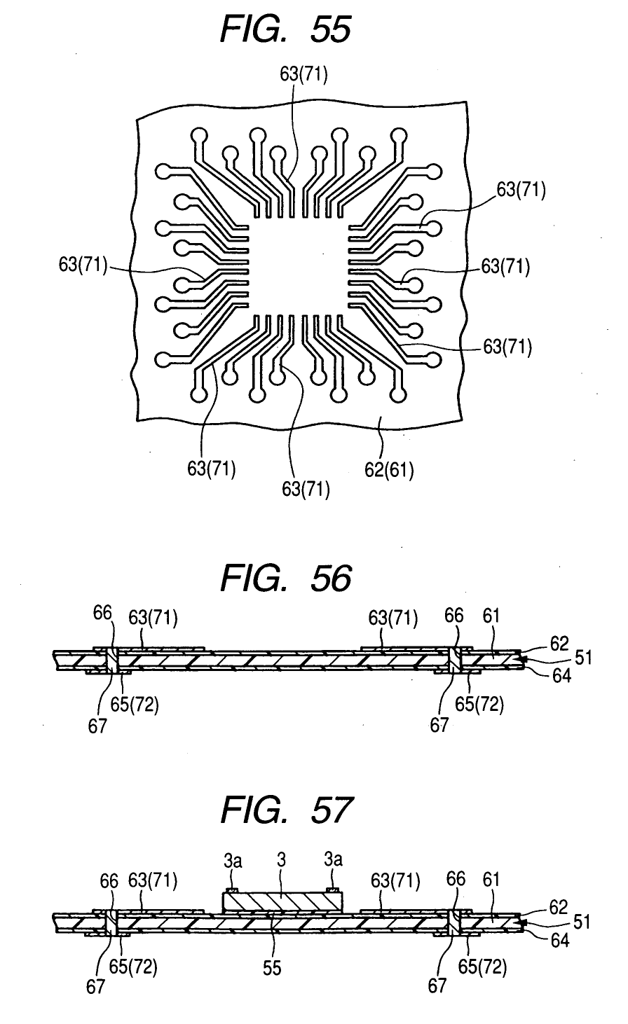

Next, the manufacturing process of the semiconductor device 1d of the present embodiment will be described. FIGS. 53 to 59 are plan views (plan views of relevant portions) or cross-sectional views (cross-sectional views of relevant portions) showing the manufacturing process of the semiconductor device 1d of the present embodiment. Of FIGS. 53 to 59, FIG. 55 is a plan view (plan view of relevant portions), and FIGS. 53, 54, and 56 to 59 are cross-sectional views (cross-sectional views of relevant portions). The cross-sectional view of FIG. 54 and the plan view of FIG. 55 correspond to the same process stage. A cross section of the region substantially corresponding to FIG. 51 is shown in the cross-sectional views of FIGS. 53, 54, and 56 to 59.

In manufacturing the semiconductor device 1d, first, the wiring board 51 is prepared. The lead frame 51 can be manufactured as follows, for example.

First, as shown in FIG. 53, the binder layers 62 and 64 are formed (applied, coated) on both sides of the insulating base material layer 61, and the conductive metal material layers (conductor layers) 71 and 72 including copper such as copper foil are adhered to both sides of the base material layer 61 via the binder layers 62 and 64. Then, as shown in FIGS. 54 and 55, the conductive metal material layers 71 and 72 on both sides of the base material layer 61 are patterned by etching. The conductor layer 63 (the connection terminal portions 52a and the wirings 52b) on the upper surface side of the wiring board 51 is formed by the patterned conductive metal material layer 71 on the upper surface side of the base material layer 61, and the conductor layer 65 (conductive land portions) on the lower surface side of the wiring board 51 is formed by the patterned conductive metal material layer 72 on the lower surface side of the base material layer 61. Then, as shown in FIG. 56, the open portions 66 are formed in the base material layer 61, and the conductor layer (metal layer, plating layer) 67 is formed by plating or the like on the side walls of the open portions 66 in the base material layer 61. In this manner, the wiring board 51 can be manufactured. When the wiring board 51 is a multilayer wiring board, the wiring board 51 can be manufactured by buildup.

As shown in FIG. 57, a die bonding step is conducted to mount the semiconductor chip 3 on the upper surface 51a of the wiring board 51 prepared as described above. In this die bonding step, the semiconductor chip 3 is adhered (bonded) via the bonding material 55 onto the upper surface 51a of the wiring board 51. The binder 55 is an insulating binding material, for example, but a conductive binding material such as silver paste can also be used. For example, the binder 55 can be applied to the substantial center portion of the upper surface 51a of the wiring board 51 to form an adhesive layer for fixing the chip, the semiconductor chip 3 can be mounted on the binder 55, and heating or the like can be conducted such that the upper surface 51a of the wiring board 51 and the undersurface of the semiconductor chip 3 are bonded together via the binder 55.

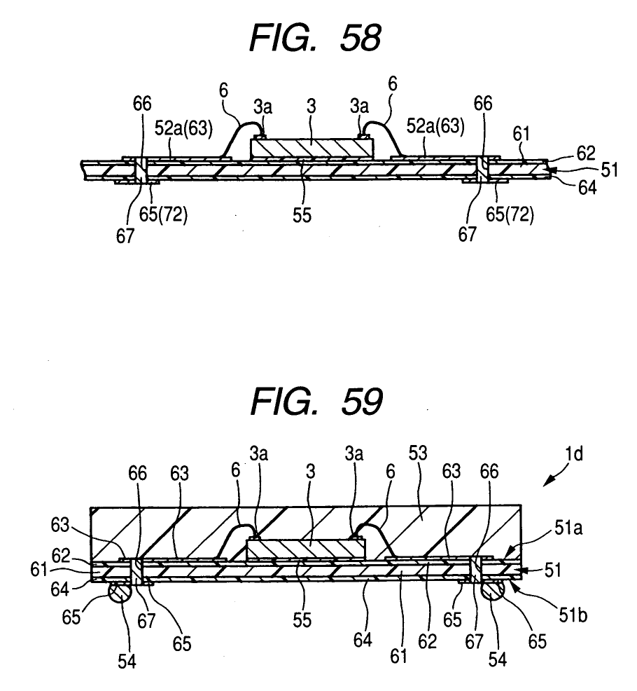

Next, as shown in FIG. 58, a wire bonding step is conducted to electrically connect, via the plural bonding wires 6, the electrodes 3a of the semiconductor chip 3 to the corresponding connection terminal portions 52a formed by the conductor layer 63 of the upper surface 51a of the wiring board 51.

Next, as shown in FIG. 59, a mold step is conducted to form the sealing resin portion 53 on the upper surface 51a of the wiring board 51 such that the sealing resin portion 53 covers the semiconductor chip 3 and the bonding wires 6.

Next, the solder balls 54 are disposed on the conductive land portions formed by the conductor layer 65 of the lower surface 51b of the wiring board 51, and solder reflow is conducted to bond and electrically connect the solder balls 54 to the conductive land portions.

When a wiring board where plural unit wiring board portions (from which one semiconductor device 1d is manufactured) are connectedly formed is used as the wiring board 51, the wiring board 51, or the wiring board 51 and the sealing resin portion 53, is cut and divided into individual (separate) semiconductor devices 1d. In this manner, the semiconductor device 1d of the present embodiment is manufactured.

Thereafter, a marking step and a sorting step are conducted with respect to the semiconductor devices 1d, and semiconductor devices 1d sorted as good products in the sorting step are shipped as products (semiconductor packages).

In the present embodiment also, effects that are substantially the same as those of the first to fourth embodiments can be obtained.

That is, in the present embodiment, the conductor layers 63 and 65 are adhered to the insulating base material layer 61 by the binder layer 62 in the wiring board 51. When a phenol resin is used for the material of the binder layer 62 that adheres the conductor layers 63 and 65 to the base material layer 61 in the wiring board 51 in contrast to the present embodiment, there is the potential for migration of the copper in the conductor layers 63 and 65 comprising a conductor material including copper to occur, and for the copper in the conductor layers 63 and 65 to disperse through the binder layer 62 and lower the reliability of the semiconductor device, as is apparent from the description in the first embodiment. In particular, there is the potential for migration of the copper (dispersion of the copper through the binder layer 62) to occur in a path 45b schematically represented by the arrow in FIG. 52 between mutually close adjacent connection terminal portions 52a or wirings 52b in the upper surface 51a of the wiring board 51 and lower the dielectric breakdown resistance between the terminal connection portions 52a or the wirings 52b of the wiring board 51 of the semiconductor device 1d.

In the present embodiment, the migration of the copper in the conductor layers (63 and 65) of the wiring board 51 (dispersion through the binder layer 62) can be suppressed or prevented by using the same material as that of the binder layer 16 of the fixing tape 9 of the first embodiment for the material of the binder layer 62 that adheres the conductor layers (63 and 65) comprising a conductor material including copper to the insulating base material layer 61 in the wiring board 51. Even if a degradation test is conducted under the strict environmental degradation conditions of 150° C./100 V, copper migration is suppressed, and the copper in the conductor layers (63 and 65) of the wiring board 51 can be prevented from being dispersed through the binder layer 62 for adhering the conductor layers to the base material layer 61 of the wiring board. Because the migration of the copper in the conductor layers (63 and 65) of the wiring board 51 can be suppressed or prevented and the anti-migration characteristics can be improved, the dielectric breakdown resistance between the connection terminal portions 52a and the wirings 52b of the wiring board 51 of the semiconductor device 1d can be improved, and insulation failure between adjacent connection terminal portions 52a and wirings 52b of the wiring board 51 of the semiconductor device 1d can be more adequately prevented. Also, the generation of a large amount of out-gas from the (binder layers 62 and 64 of the) wiring board 51 due to heating can be suppressed or prevented. Consequently, the reliability of the semiconductor device can be improved, and the manufacturing yield of the semiconductor device can be improved.

### Sixth Embodiment

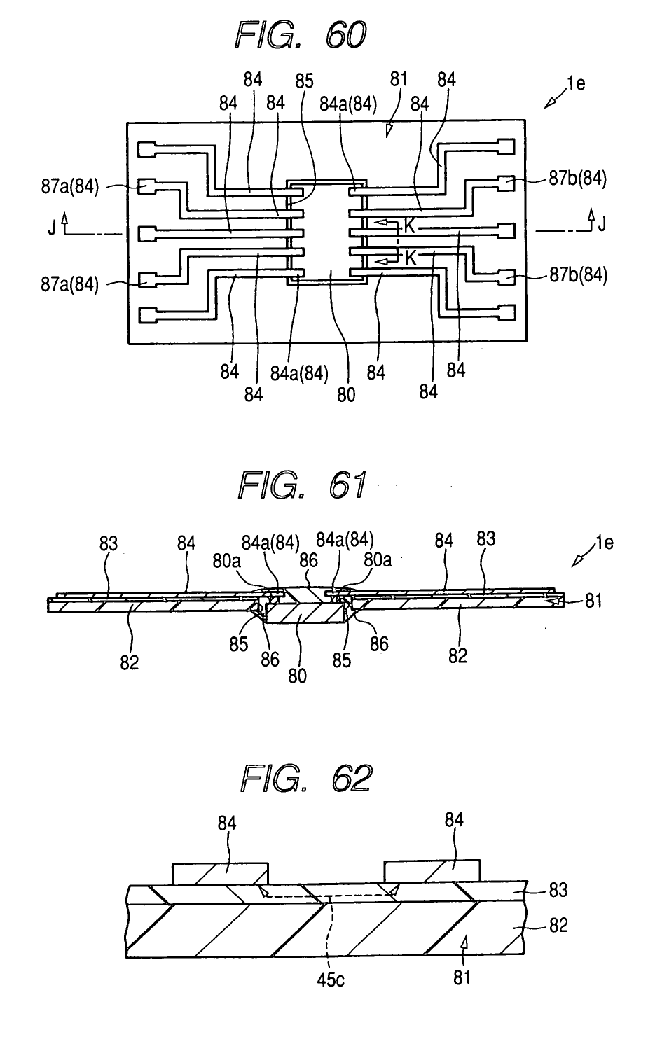

FIG. 60 is a plan perspective view of a semiconductor device 1e pertaining to a sixth embodiment of the invention. FIG. 61 is a cross-sectional view (side sectional view), and FIG. 62 is a cross-sectional view of relevant portions (partially enlarged cross-sectional view). FIG. 60 corresponds to a plan view when seen through a sealing resin portion 86. The cross section along line J-J of FIG. 60 substantially corresponds to FIG. 61, and the cross section along line K-K of FIG. 60 substantially corresponds to FIG. 62.

The present embodiment is one where the invention is applied to a tape carrier package (TCP) semiconductor device 1e, in which a semiconductor chip is mounted on a tape carrier (film carrier) comprising an insulating film on which a wiring pattern is formed. The TCP is mounted and used on a liquid crystal display (LCD) panel of a liquid crystal display device, for example.

The semiconductor device (TCP) 1e of the present embodiment shown in FIGS. 60 to 62 is a TCP or TCP semiconductor device, and has a structure where a semiconductor chip 80 is mounted on a tape carrier 81 (film carrier, flexible wiring board, wiring board).

The tape carrier 81 includes an insulating base film (insulating film, insulating base material layer) 82 comprising polyimide, for example, and plural wirings (wiring pattern) 84 formed (adhered) via a binder layer 83 on the surface of the base film 82. The plural wirings 84 comprise (a pattern of) conductor layers adhered via the binder layer 83 on (the insulating base material layer of) the base film 82.

The base film 82 has plasticity, is soft, and can bend. A sprocket hole (not shown) used in order to send the tape carrier 81 can also be formed in both sides of the base film 82. A solder resist layer (not shown) can also be formed, so as to cover the wirings 84, on the surface of the tape carrier 81 in order to protect and insulate the wirings 84. A device hole 85 is formed in the base film 82 in a region for mounting the semiconductor chip 80. Inner lead portions 84a, which are end portions at one side of the wirings 80, are exposed in a state where they protrude into the air in the device hole 85, and bump electrodes 80a of the semiconductor chip 80 are electrically connected to the inner lead portions 84a. The portions where the inner lead portions 84a of the wirings 84 and the bump electrodes 80a of the semiconductor chip 80 are connected are covered and protected by the sealing resin portion 86. Outer lead portions (external connection-use terminals, end portions at the opposite side from the inner lead portions 84a) 87a at the input side of the wirings 84 and outer lead portions (external connection-use terminals, end portions at the opposite side from the inner lead portions 84a) 87b at the output side of the wirings 84 are exposed in a state where they are backed by the base film 82, and are used in order to connect to an external circuit (e.g., an LCD panel).

In the present embodiment also, the same material as that of the binder layer 16 of the fixing tape 9 of the first embodiment is used for the material of the binder layer 83 that adheres the wirings 84 of the tape carrier 81 to the insulating base film 82. That is, the main component of the binder of the binder layer 83 of the tape carrier 81 is an amine-curable epoxy resin and not a phenol resin. Consequently, the binder layer 83 of the tape carrier 81 is a thermosetting binder and does not substantially include phenol resin, and it is more preferable for the content of the amine-curable epoxy resin to be at least 70% by weight. It is also preferable for the binder layer 83 of the tape carrier 81 to include acrylonitrile butadiene rubber (NBR) in addition to the amine-curable epoxy resin. The materials that are particularly preferable for the epoxy resin and curing agent used in the binder layer 83 of the tape carrier 81 and the preferable range of the content of the NBR are the same as those for the binder layer 16 of the fixing tape 9 of the first embodiment, so description thereof will be omitted here.

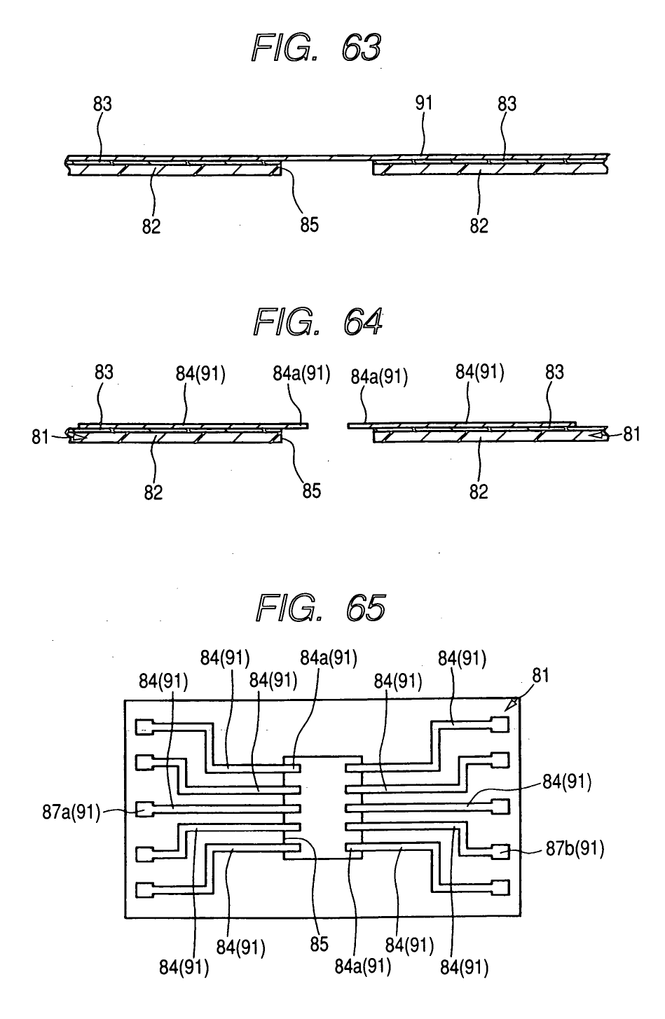

Next, the manufacturing process of the semiconductor device 1e of the present embodiment will be described. FIGS. 63 to 67 are plan views (plan views of relevant portions) or cross-sectional views (cross-sectional views of relevant portions) showing the manufacturing process of the semiconductor device 1e of the present embodiment. Of FIGS. 63 to 67, FIG. 65 is a plan view (plan view of relevant portions), and FIGS. 63, 64, 66 and 67 are cross-sectional views (cross-sectional views of relevant portions). The cross-sectional view of FIG. 64 and the plan view of FIG. 65 correspond to the same process stage. A cross section or the region substantially corresponding to FIG. 61 is shown in the cross-sectional views of FIGS. 63, 64, 66 and 67

In manufacturing the semiconductor device 1e, first, the tape carrier (film carrier, flexible wiring board) 81 is prepared. The tape carrier 81 can be manufactured as follows, for example.

First, as shown in FIG. 63, the binder layer 83 is formed (applied, coated) on one side of the base film 82 in which various holes (including the device hole 85) are formed as needed by punching, and the conductive metal material layer (conductor layer) 91 including copper such as copper foil is adhered to the base film 82 via the binder layer 83. Then, as shown in FIGS. 64 and 65, the conductive metal material layer 91 is patterned by etching. The wirings 84 (including the inner leads portions 84a and the outer lead portions 87a and 87b) of the tape carrier 81 are formed by the patterned conductive metal material layer 91. Thereafter, a plating layer is formed on the surface of the wirings 84 as needed, and a solder resist layer (not shown) is formed on the base film 82 such that it partially covers the wirings 84 and so that the inner lead portions 84a and the outer lead portions 87a and 87b are exposed. In this manner, the tape carrier 81 can be formed.

The inner lead portions 84a can also be backed by the base film 82 without forming the device hole 85 in the region of the base film 82 for mounting the semiconductor chip (i.e., such that the inner lead portions 84a are formed on the base film 82 via the binder layer 83). Consequently, the TCP or TCP semiconductor device referred to in the present embodiment includes chip on film (COF) and a COF semiconductor device where the device hole is not formed in the base film 82.

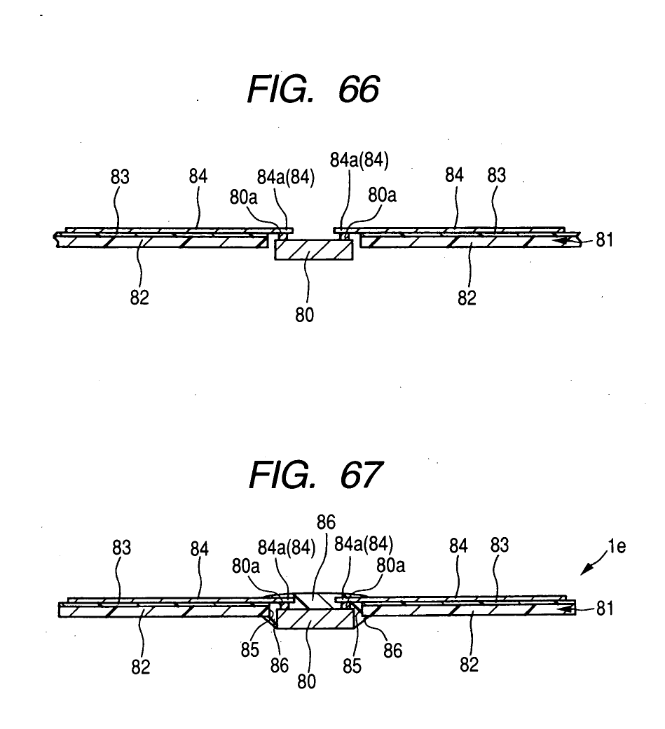

Next, as shown in FIG. 66, the semiconductor chip 80 is mounted (inner lead bonding) on a predetermined position (inner lead portions 84a of the device hole 85) of the tape carrier 81. Similar to the semiconductor chip 3, the semiconductor chip 80 is one where various semiconductor elements or semiconductor integrated circuits are formed on a semiconductor substrate (semiconductor wafer) comprising single crystal silicon, for example, the undersurface of the semiconductor substrate is grinded as needed, and the semiconductor substrate is divided into the semiconductor chips 80 by dicing. When the semiconductor chip 80 is to be bonded to the tape carrier 81, the bump electrodes (gold (Au) bumps) 80a of the semiconductor chip 80 are bonded and electrically connected to the inner lead portions 84a of the wirings 84 by thermocompression or ultrasonic bonding.

Next, as shown in FIG. 67, the semiconductor chip 80 is coated with sealing resin (resin material) using potting or the like, and heated and cured to form the sealing resin portion 86. Thus, the portions where the inner lead portions 84a and the bump electrodes 80a of the semiconductor chip 80 are connected are covered and protected by the sealing resin portion 86. The connection between the tape carrier 81 and the semiconductor chip 80 is strengthened by the sealing resin portion 86, and the reliability of the electrical connection between the inner lead portions 84a and the bump electrodes 80a of the semiconductor chip 80 is improved. Thereafter, a marking step and an inspection step are conducted as needed, and the tape carrier 81 is cut at predetermined positions and divided (separated) into individual semiconductor devices 1e (TCP semiconductor devices). In this manner, the semiconductor device 1e of the present embodiment is manufactured.

In the present embodiment also, effects that are substantially the same as those of the first to fifth embodiments can be obtained.

That is, in the present embodiment, the wirings 84 are adhered to the insulating base film 82 by the binder layer 83 in the tape carrier 81. When a phenol resin is used for the material of the binder layer 83 that adheres the wirings 84 to the base film 82 in the tape carrier 81 in contrast to the present embodiment, there is the potential for migration of the copper in the wirings 84 comprising a conductor material including copper to occur, and for the copper in the wirings 84 to disperse through the binder layer 83 and lower the reliability of the semiconductor device, as is apparent from the description in the first embodiment. In particular, there is the potential for migration of the copper (dispersion of the copper through the binder layer 83) to occur in a path 45c schematically represented by the arrow in FIG. 62 between mutually close adjacent wirings 84 in the surface of the tape carrier 81 and lower the dielectric breakdown resistance between the wirings 84 of the tape carrier 81 of the semiconductor device 1e.

In the present embodiment, the migration of the copper in the wirings 84 of the tape carrier 81 (dispersion through the binder layer 83) can be suppressed or prevented by using the same material as that of the binder layer 16 of the fixing tape 9 of the first embodiment for the material of the binder layer 83 that adheres the wirings 84 comprising a conductor material including copper to the insulating base film 82. Even if a degradation test is conducted under the strict environmental degradation conditions of 150° C./100 V, copper migration is suppressed, and the copper in the wirings 84 of the tape carrier 81 can be prevented from being dispersed through the binder layer 83 for adhering the wirings 84 to the base film 82 of the tape carrier 81. Because the migration of the copper in the wirings 84 of the tape carrier 81 can be suppressed or prevented and the anti-migration characteristics can be improved, the dielectric breakdown resistance between the wirings 84 of the tape carrier 81 of the semiconductor device 1e can be improved, and insulation failure between adjacent wirings 84 of the tape carrier 81 of the semiconductor device 1e can be more adequately prevented. Also, the generation of a large amount of out-gas from the (binder layer 83 of the) tape carrier 81 due to heating can be suppressed or prevented. Consequently, the reliability of the semiconductor device can be improved, and the manufacturing yield of the semiconductor device can be improved.

The invention devised by the present inventors has been specifically described above on the basis of embodiments thereof, but the present invention is not limited to these embodiments and can be variously modified in a range that does not depart from the gist thereof.

The present invention is suitably applied to a semiconductor package semiconductor device and a technique for manufacturing the same.

What is claimed is:

1. A method of manufacturing a semiconductor device comprising the steps of:
(a) preparing a lead frame that includes a chip mounting portion and plural lead portions disposed around the chip mounting portion and comprises a conductor material including copper;
(b) adhering a first member that includes a binder layer whose main component is an amine-curable epoxy resin to the plural lead portions via the binder layer;
(c) mounting a semiconductor chip including plural electrodes on the chip mounting portion;
(d) electrically connecting the plural lead portions to the plural electrodes of the semiconductor chip via plural wires;
(e) forming a sealing resin portion that seals the semiconductor chip, the chip mounting portion, the plural wires, the plural lead portions and the first member; and
(f) cutting the lead frame.

2. The semiconductor device manufacturing method of claim 1, wherein the binder layer does not include a phenol resin.

3. The semiconductor device manufacturing method of claim 1, wherein the binder layer includes at least 70% by weight of the amine-curable epoxy resin.

4. The semiconductor device manufacturing method of claim 1, wherein the binder layer further includes acrylonitrile butadiene rubber.

5. The semiconductor device manufacturing method of claim 4, wherein the binder layer includes no more than 30% by weight of the acrylonitrile butadiene rubber.

6. The semiconductor device manufacturing method of claim 1, wherein the binder layer includes trifunctional amine as a curing agent.

7. The semiconductor device manufacturing method of claim 1, wherein the first member comprises a tape for fixing the plural lead portions of the lead frame.

8. The semiconductor device manufacturing method of claim 1, wherein the first member functions as the chip mounting portion, and in the step (c), the semiconductor chip is mounted on the first member functioning as the chip mounting portion.

9. A semiconductor device comprising:
a semiconductor chip including plural electrodes;
plural lead portions;
plural wires that electrically connect the plural lead portions to the plural electrodes of the semiconductor chip;
a first member that includes a binder layer and is adhered to the plural lead portions via the binder layer;
a sealing resin portion that seals the semiconductor chip, the plural wires, the plural lead portions and the first member,
wherein the plural lead portions comprise a conductor material including copper, and
the binder layer includes an amine-curable epoxy resin as its main component.

10. The semiconductor device of claim 9, wherein the binder layer does not include a phenol resin.

11. The semiconductor device of claim 9, wherein the binder layer includes at least 70% by weight of the amine-curable epoxy resin.

12. The semiconductor device of claim 9, wherein the binder layer further includes acrylonitrile butadiene rubber.

13. The semiconductor device of claim 12, wherein the binder layer includes no more than 30% by weight of the acrylonitrile butadiene rubber.

14. The semiconductor device of claim 9, wherein the binder layer includes trifunctional amine as a curing agent.

15. The semiconductor device of claim 9, wherein the first member comprises a tape for fixing the plural lead portions of a lead frame used when manufacturing the semiconductor device.

16. The semiconductor device of claim 9, wherein the semiconductor chip is mounted on the first member.

17. A semiconductor device comprising:
a wiring board including an insulating base material layer, a binder layer on the base material layer, and a conductor layer adhered on the base material layer via the binder layer; and
a semiconductor chip that includes plural electrodes and is mounted on the wiring board,
wherein the plural electrodes of the semiconductor chip are electrically connected to the conductor layer of the wiring board,
the conductor layer of the wiring board comprises a conductor material including copper, and
the binder layer of the wiring board includes an amine-curable epoxy resin as its main component.

18. The semiconductor device of claim 17, wherein the binder layer does not include a phenol resin.

19. The semiconductor device of claim 17, wherein the binder layer includes at least 70% by weight of the amine-curable epoxy resin.

20. The semiconductor device of claim 17, wherein the binder layer further includes acrylonitrile butadiene rubber.

21. The semiconductor device of claim 20, wherein the binder layer includes no more than 30% by weight of the acrylonitrile butadiene rubber.
